(19) United States
(12) Patent Application Publication
(10) Pub. No.: US 2003/0139027 A1
(43) Pub. Date: Jul. 24, 2003

(54) Semiconductor integrated circuit device and a method of manufacturing the same

(76) Inventors: Shuji Ikeda, Koganei (JP); Masayuki Kojima, Kokubunji (JP); Akira Takamatsu, Hamura (JP); Yasuko Yoshida, Sayama (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/345,958

(22) Filed: Jan. 17, 2003

Related U.S. Application Data
(63) Continuation of application No. 09/468,868, filed on Dec. 21, 1999, now abandoned.

(30) Foreign Application Priority Data
Dec. 21, 1998 (JP) 10-362551

(51) Int. Cl. H01L 21/3205

(52) U.S. Cl. 438/592

(57) ABSTRACT

A gate electrode 8A of a memory cell selection MISFET Qs, which forms part of a memory cell, and gate electrodes 8B and 8C of an n-channel type MISFET Qn and a p-channel type MISFET Qp, which forms part of a logic LSI, are formed by an SiGe layer 28 and a W layer 29 deposited above the layer 28. A silicon nitride film 9 is formed above the gate electrodes 8A, 8B, and 8C to realize self-aligned contact holes (SAC).

### BACKGROUND OF THE INVENTION

The present invention relates to a semiconductor integrated circuit device and a manufacturing method thereof, and particularly to a technique effective for a semiconductor integrated circuit device which is mixedly mounted with a memory LSI and a logic LSI and for the manufacturing method thereof.

In semiconductor devices in which MISFETs (Metal Insulator Semiconductor Field Effect Transistors) constitute an integrated circuit, the drop of the threshold voltage (Vth) occurs apparently due to increase of capacitance coupling of sources, drains, and channels as downsizing of the MISFETS proceeds. Consequently, the leakage current increases in the sub-threshold area or the operation margins of the circuit are reduced, resulting in a problem. The increase of the leakage current causes, for example, a serious problem of deterioration of the refresh characteristic in a DRAM (Dynamic Random Access Memory).

To prevent a drop of the threshold voltage of a downsized short channel MISFET, countermeasures are taken, e.g., the impurity density is increased or the gate insulating film is thinned. However if the impurity density of the substrate is increased, the electric field intensity of a storage node increases near the semiconductor region in the case of the DRAM described above, thereby causing problems of deterioration of the refresh characteristic due to increase of the leakage current and increase of the parasitic capacitance of bit lines. In addition, if the impurity density of a substrate is increased, the change of the threshold voltage is increased due to application of a substrate bias, i.e., a so-called substrate bias effect is increased. Therefore, in the case of a DRAM, a rise of the threshold voltage is increased when writing data, and a high voltage is required when boosting the voltage of the word line potential. Consequently, the film thickness of the gate insulating film may not be thinned from the viewpoint of ensuring a withstand voltage.

Limitations to the film thickness of the gate insulating film as described above lead to serious problems, particularly in a system LSI in which a DRAM and a logic LSI are mixedly mounted. That is, high speed operation is required for the logic part of the system LSI, and from this viewpoint, it is eagerly required to form a thinner gate insulating film while the gate insulating film requires certain film thickness at the memory part. Consequently, the film thickness must be changed between the memory part and the logic part, so that the burdens to processing are enlarged.

The threshold voltage of the MISFET also changes due to the difference between the work functions of the gate electrode material and the substrate. Hence, a so-called dual gate CMOS structure has been proposed as a countermeasure for preventing the reduction of the threshold voltage of a downsized MISFET. In this structure, the gate electrode of an n-channel type MISFET and the gate electrode of a p-channel type MISFET are respectively formed of n-type polycrystal silicon and p-type polycrystal silicon, and both gate electrodes are of a surface channel type. Also, there has been a proposal for a CMOS structure in which the gate electrodes of the n-channel type MISFET and the p-channel type MISFET are formed of high melting point metal or a silicide thereof which has a substantially middle work function, namely, a work function midway between the n-type polycrystal silicon and the p-type polycrystal silicon.

In case of the dual gate CMOS structure described above, the gate electrode (n-type polycrystal silicon) of the n-channel type MISFET and the gate electrode (p-type polycrystal silicon) of the p-channel type MISFET can be connected with each other by forming both electrodes in a polycide (a high-melting point metal silicon/polycrystal silicon) structure. In this case, however, there is a problem of an increase in resistance due to mutual diffusion between the n-type impurity (phosphorus) in the n-type polycrystal silicon film and the p-type impurity (boron) in the p-type polycrystal silicon film. In addition, since it is necessary to implant selectively the n-type impurity and the p-type impurity into a polycrystal silicon film deposited on a substrate, problems appear in that the number of ion-implanting steps and the number of photomasks to be used must be increased and that the dry-etching speed differs between the n-type polycrystal silicon and the p-type polycrystal silicon so that the substrate is more etched over and more deeply removed in both sides of one gate electrode than in both sides of the other gate electrode during processing of the gate electrodes. Further, the dual gate CMOS structure leads to a greater difference between the threshold voltages of the n-channel type MISFET and the p-channel type MISFET than an normal CMOS in which gate electrodes are formed of only n-type polycrystal silicon, resulting in a problem that the equalization of the threshold voltages is complicated.

Meanwhile, in case of the latter CMOS structure in which gate electrodes are formed of high-melting-point metal or silicide thereof, this kind of electrode material is directly deposited on a gate insulating film, and it has been, therefore, pointed out that there are problems of the tightness of contact therebetween and harmful influences onto the characteristics of the gate insulating film from the electrode material.

As a countermeasure for preventing the drop of the threshold voltage of a downsized MISFET without increasing the impurity density of the structure, there has been a proposal for a CMOS structure in which an alloy consisting of polycrystal or monocrystal silicon and Ge (germanium) (the alloy referred to hereinafter “SiGe”) and having a substantially middle work function between that of an n-type polycrystal silicon and a p-type polycrystal silicon is used as a gate electrode material.

For example, Japanese Patent Application Laid-Open Publication No. 5-235335 discloses a MISFET comprising a gate electrode of a two-layer structure in which a high-melting-point metal layer (or a high-melting point metal silicide layer) is layered on an upper part of a SiGe layer doped with n- or p-type impurities.

Japanese Patent Application Laid-Open Publication No. 7-202178 discloses a MISFET comprising a gate electrode of a two-layer structure in which a SiGe layer is selectively grown on an upper part of a polycrystal silicon layer.

Japanese Patent Application Laid-Open Publication No. 9-45903 discloses a technique for forming an oxide film on the surface of a gate electrode made of SiGe containing impurities for the purpose of avoiding short-circuiting errors which are caused between gate electrodes and wires through impurities diffused in pin holes existing in interlayer insulating films.

Japanese Patent Application Laid-Open Publication No. 6-69434 discloses a technique for attaining a high-speed semiconductor integrated circuit device of a bipolar CMOS type construction by using SiGe having a lower resistance than polycrystal silicon as materials of gate electrodes of MISFETs and base lead electrodes of bipolar transistors.

### SUMMARY OF THE INVENTION

In recent years, developments have been made for a so-called memory-logic mixed LSI in which a memory LSI such as a DRAM and a logic LSI are mixedly mounted on one same semiconductor substrate. However, in the memory-logic mixed LSI, the characteristic of the element required for a memory section and that required for a logic section are different from each other. Consequently, it is difficult to optimize the characteristic of each element and the manufacturing steps thereof are complicated.

An object of the present invention is to provide a technique capable of highly improving the performance of the memory-logic mixed LSI.

Another object of the present invention is to provide a technique capable of promoting downsizing and high integration of the memory-logic mixed LSI

Also, another object of the present invention is to provide a technique capable of simplifying the steps of manufacturing the memory-logic mixed LSI.

The above-described and other objects of the present invention and the novel features thereof will be clearly understood from the description of the present specification and the drawings attached hitherto.

Representative aspects of the invention disclosed in the present application will be summarized as follows.

(1) According to an aspect of the present invention, a semiconductor integrated circuit device comprises a first MISFET constructing a memory element and formed in a first region of a semiconductor substrate, a second MISFET of an n-channel type formed in a second region, a third MISFET of a p-channel type formed in a third region, wherein each of the first to third MISFETs has a gate electrode formed so as to include an SiGe layer and a metal layer or metal silicide layer formed above the SiGe layer, and a first insulating layer is formed on each of the gate electrode.

(2) According to another aspect of the present invention, each of the second and third MISFETs has a source and a drain having surfaces on which a silicide layer is formed and the first MISFET has a source and a drain having surfaces on which no silicide layer is formed, in the semiconductor integrated circuit device described in the above article (1).

(3) According to an aspect of the present invention, a method of manufacturing a semiconductor integrated circuit device comprises a step of forming a first conductive film on a main surface of a semiconductor substrate, forming a first insulating film above the first conductive film, patterning thereafter the first insulating film and the first conductive film, thereby to form a first MISFET forming part of a memory element and a first insulating layer covering an upper portion thereof in a first region of the semiconductor substrate, to form a gate electrode of a second MISFET of an n-channel type and a first insulating layer covering an upper portion thereof in a second region, and to form a gate electrode of a third MISFET of a p-channel type and a first insulating layer covering an upper portion thereof in a third region, wherein the first conductive film forming part of the gate electrode of each of the gate electrodes of the first to third MISFETs is formed so as to include an SiGe layer and a metal layer or metal silicide layer formed thereon.

(4) According to another aspect of the present invention, after the gate electrode of each of the first to third MISFETs are formed, and the p-channel type MISFET is formed, the method of manufacturing a semiconductor integrated circuit device described in the above article (3) further comprises:

a step (a) of forming a second insulating layer made of a material which is substantially equal to a material of the first insulating layer, on side walls of each of the gate electrodes; a step (b) of forming an interlayer insulating film having an etching speed different from etching speeds of the first and second insulating layers, as an upper layer of the first to third MISFETs;

a step (c) of etching the interlayer insulating film thereby to form a first contact hole above a source and a drain of the first MISFET by a self-alignment manner with respect to the gate electrode of the first MISFET;

a step (d) of forming a plug which is made of polycrystal silicon and doped with impurities of a conductivity type equal to a conductivity type of the source and drain of the first MISFET;

a step (e) of etching the interlayer insulating film thereby to form a second contact hole above a source and a drain of the second MISFET and a third contact hole above a source and a drain of the third MISFET;

a step (f) of forming a second conductive film above the interlayer insulating film, including insides of the second and third contact holes; and

a step (g) of subjecting the semiconductor substrate to a heat treatment thereby to form a suicide layer on surfaces of the source and drain of each of the second and third MISFETs, through reaction caused between the semiconductor substrate and the second conductive film.

### BRIEF DESCRIPTION OF THE DRAWINGS

FIG. 1 is a cross-sectional view of a main part of a semiconductor substrate, showing a DRAM-logic mixed LSI according to example embodiment 1 of the present invention.

FIG. 2 is a cross-sectional view of a main part of the semiconductor integrated circuit device shown in FIG. 1 in a manufacturing step thereof.

FIG. 3 is a cross-sectional view of a main part of a semiconductor substrate, showing a process step in a method of manufacturing a DRAM-logic mixed LSI according to the embodiment 1 of the present invention.

FIG. 4 is a cross-sectional view of a main part of a semiconductor substrate, showing another step in the method of manufacturing a DRAM-logic mixed LSI according to the embodiment 1 of the present invention.

FIG. 5 is a cross-sectional view of a main part of a semiconductor substrate, showing a further step in the method of manufacturing a DRAM-logic mixed LSI according to the embodiment 1 of the present invention.

FIG. 6 is a cross-sectional view of a main part of a semiconductor substrate, showing another step in the method of manufacturing a DRAM-logic mixed LSI according to the embodiment 1 of the present invention.

FIG. 7 is a cross-sectional view of a main part of a semiconductor substrate, showing an additional step in the method of manufacturing a DRAM-logic mixed LSI according to the embodiment 1 of the present invention.

FIG. 8 is a cross-sectional view of a main part of a semiconductor substrate, showing another step in the method of manufacturing a DRAM-logic mixed LSI according to the embodiment 1 of the present invention.

FIG. 9 is a cross-sectional view of a main part of a semiconductor substrate, showing a further step in the method of manufacturing a DRAM-logic mixed LSI according to the embodiment 1 of the present invention.

FIG. 10 is a cross-sectional view of a main part of a semiconductor substrate, showing an additional step in the method of manufacturing a DRAM-logic mixed LSI according to the embodiment 1 of the present invention.

FIG. 11 is a cross-sectional view of a main part of a semiconductor substrate, showing another step in the method of manufacturing a DRAM-logic mixed LSI according to the embodiment 1 of the present invention.

FIG. 12 is a cross-sectional view of a main part of a semiconductor substrate, showing a further step in the method of manufacturing a DRAM-logic mixed LSI according to the embodiment 1 of the present invention.

FIG. 13 is a cross-sectional view of a main part of a semiconductor substrate, showing a further step in the method of manufacturing a DRAM-logic mixed LSI according to the embodiment 1 of the present invention.

FIG. 14 is a cross-sectional view of a main part of a semiconductor substrate, showing another step in the method of manufacturing a DRAM-logic mixed LSI according to the embodiment 1 of the present invention.

FIG. 15 is a cross-sectional view of a main part of a semiconductor substrate, showing an additional step in the method of manufacturing a DRAM-logic mixed LSI according to the embodiment 1 of the present invention.

FIG. 16 is a cross-sectional view of a main part of a semiconductor substrate, showing a further step in the method of manufacturing a DRAM-logic mixed LSI according to the embodiment 1 of the present invention.

FIG. 17 is a cross-sectional view of a main part of a semiconductor substrate, showing a further step in the method of manufacturing a DRAM-logic mixed LSI according to the embodiment 1 of the present invention.

FIG. 18 is a cross-sectional view of a main part of a semiconductor substrate, showing another step in the method of manufacturing a DRAM-logic mixed LSI according to the embodiment 1 of the present invention.

FIG. 19 is a cross-sectional view of a main part of a semiconductor substrate, showing a further step in the method of manufacturing a DRAM-logic mixed LSI according to the embodiment 1 of the present invention.

FIG. 20 is a cross-sectional view of a main part of a semiconductor substrate, showing another step in the method of manufacturing a DRAM-logic mixed LSI according to the embodiment 1 of the present invention.

FIG. 21 is a cross-sectional view of a main part of a semiconductor substrate, showing a further step in the method of manufacturing a DRAM-logic mixed LSI according to the embodiment 1 of the present invention.

FIG. 22 is a cross-sectional view of a main part of a semiconductor substrate, showing a still further step in the method of manufacturing a DRAM-logic mixed LSI according to the embodiment 1 of the present invention.

FIG. 23 is a cross-sectional view of a main part of a semiconductor substrate, showing a further step in the method of manufacturing a DRAM-logic mixed LSI according to the embodiment 1 of the present invention.

FIG. 24 is a cross-sectional view of a main part of a semiconductor substrate, showing an additional step in the method of manufacturing a DRAM-logic mixed LSI according to example embodiment 1 of the present invention.

FIG. 25 is a cross-sectional view of a main part of a semiconductor substrate, showing a method of manufacturing a DRAM-logic mixed LSI according to example embodiment 2 of the present invention.

FIG. 26 is a cross-sectional view of a main part of a semiconductor substrate, showing the method of manufacturing a DRAM-logic mixed LSI according to the embodiment 2 of the present invention.

FIG. 27 is a cross-sectional view of a main part of a semiconductor substrate, showing the method of manufacturing a DRAM-logic mixed LSI according to the embodiment 2 of the present invention.

FIG. 28 is a cross-sectional view of a main part of a semiconductor substrate, showing the method of manufacturing a DRAM-logic mixed LSI according to example embodiment 3 of the present invention.

FIG. 29 is a cross-sectional view of a main part of a semiconductor substrate, showing the method of manufacturing a DRAM-logic mixed LSI according to the embodiment 3 of the present invention.

### DESCRIPTIONS OF THE PREFERRED EMBODIMENTS

In the following, embodiments of the present invention will now be explained in detail with reference to the drawings. In all of the figures related to the example embodiments, those components having one and the same function are denoted by the same reference symbol. Also, repetitious explanation of those components with regard to each of the example embodiments will be omitted for purposes of brevity.

(Embodiment 1)

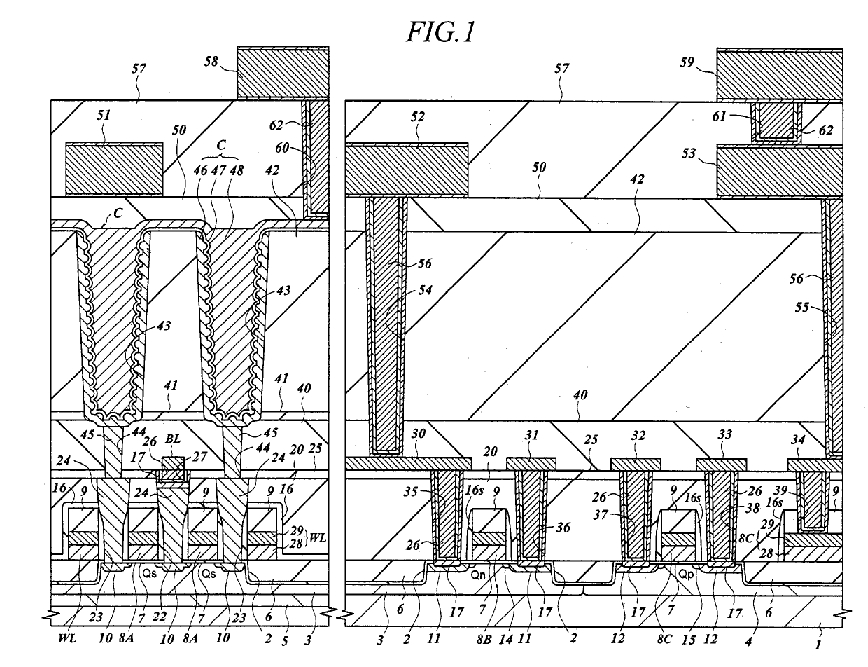

FIG. 1 is a cross-sectional view of a main part of a semiconductor substrate in which a DRAM and a logic LSI are mixedly mounted, according to a semiconductor integrated circuit device as the first embodiment of the present invention. In this figure, the left part (first region) shows a part of the memory array of a DRAM and the right part (second and third regions) show a part of a logic LSI comprising an n-channel type MISFET and a p-channel type MISFET.

For example, an element separation groove 2, p-type wells 3, and n-type wells 4 and 5 are formed above the main surface of a semiconductor substrate 1 made of monocrystal silicon. The element separation groove 2 comprises a groove formed in the semiconductor substrate 1 and a silicon oxide film 6 embedded inside the groove.

Formed in the p-type well 3 in the first region are n-channel type memory cell selection MISFETs Qs which form a part of memory cells of the DRAM. Formed in the p-type well 3 in the second region are n-channel type MISFETs Qn which form a part of the logic LSI. Formed in the n-type well 4 in the third region are p-channel type MISFETs Qp which form another part of the logic LSI. The p-type well 3 in the first region is electrically separated from the semiconductor substrate by an n-type well 5 formed under the well 3, in order to prevent noise from entering into the memory array from other regions (for example, from an in/out circuit, not shown) of the semiconductor substrate 1.

The memory cell selection MISFET Qs of the DRAM mainly comprises a gate insulating film 7, agate electrode 8A formed above the film 7, and a pair of n-type semiconductor regions 10 (source and drain) formed in the p-type well 3 in both sides of the gate electrode 8A. The gate electrode 8A of the memory cell selection MISFET Qs is formed to be integrated with a word line WL.

The n-channel type MISFET Qn, which forms a part of the logic LSI, mainly comprises a gate insulating film 7, a gate electrode 8B formed above the film 7, and a pair of n⁺-type semiconductor regions 11 (source and drain) formed in the p-type well 3 in both sides of the gate electrode 8B. In addition, the p-channel type MISFET Qp, which forms a part of the logic LSI, mainly comprises a gate insulating film 7, a gate electrode 8C formed thereon, and a pair of p⁺-type semiconductor regions 12 (source and drain) formed in the n-type well in both sides of the gate electrode 8C.

Each of the gate insulating films 7 of the memory cell selection MISFET Qs, n-channel type MISFET Qn, and p-channel type MISFET Qp is formed of a silicon oxide film or a silicon oxynitride film. Also, each of the gate electrodes 8A, 8B, and 8C of the memory cell selection MISFET Qs, n-channel type MISFET Qn, and p-channel type MISFET Qp is formed of a SiGe layer 28 and a W layer 29 deposited thereon (directly or with a barrier layer made of TiN (titanium nitride) or WN (tungsten nitride) inserted therebetween), and a silicon nitride layer 9 is formed as an upper part thereof.

Thus, in the semiconductor integrated device according to the present embodiment, the gate electrode 8A of the memory cell selection MISFET Qs, forming part of a memory cell of a DRAM, and the gate electrodes 8B and 8C of the n-channel type MISFET Qn and p-channel type MISFET Qp, forming part of a logic LSI, are formed of a SiGe layer 28 and a W layer 29 deposited thereon (directly or with a barrier layer inserted therebetween).

The SiGe layer 28 is doped with p-type impurities (boron) in order to reduce the resistance value and to set the work function at a substantially middle value between that of the work functions of n-type polycrystal silicon and p-type polycrystal silicon. The ratio of Si to Ge in the SiGe layer 28 is about Si:Ge=50 atom %:50 atom %, for example, although the ratio depends on the value of the threshold voltage to be set. The W layer 29 is layered above the SiGe layer 28 in order to reduce further the resistance values of the gate electrodes 8A, 8B, and 8C. Also, if mutual reaction is considered to occur at the interface between the W layer 29 and the SiGe layer 28, a barrier layer made of TiN (titanium nitride) or WN (tungsten nitride) is provided between both layers upon requirements.

Since the gate electrodes 8A, 8B, and 8C of the memory cell selection MISFET Qs, n-channel type MISFET. On, and p-channel type MISFET Qp are formed in the structure as described above, the work functions of the gate electrodes (8A, 8B, and 8B) can be set to be at a substantially midway between the work function (about 4.15 V) of the n-type polycrystal silicon and the work function (about 5.15 V) of the p-type polycrystal silicon. Accordingly, a drop of the threshold voltage of the MISFET (Os, Qn, or Qp) can be prevented without increasing the impurity density of the semiconductor substrate 1 (including the p-type well 3 and n-type well 4).

The source and drain of the n-channel type MISFET Qn and the p-channel type MISFET Qp, which form part of the logic LSI, are constructed in a LDD (Lightly Doped Drain) structure in order to restrict short channel effects caused by an increase of the intensity of the electric field at the end portions of the sources and drains. That is, the source and drain of the n-channel type MISFET Qn are constructed by a pair of n⁺-type semiconductor regions 11 having a high impurity density and a pair of n-type semiconductor regions 14 having a low impurity density which are formed inside the regions 11. The source and drain of the p-channel type MISFET Qp are constructed by a pair of p⁺-type semiconductor regions 12 having a high impurity density and a pair of p-type semiconductor regions 15 having a low impurity density which are formed inside the regions 12. Side wall spacers 16s for constituting the LDD structure as described above are formed respectively on the side walls of the gate electrodes 8B and 8C of the n-channel type MISFET Qn and the p-channel type MISFET Qp.

In addition, a silicide layer 17 made of Co (cobalt) silicide, or Ti (titanium) silicide is formed on each of the surfaces of the sources and drains (n⁺-type semiconductor regions 11 and p⁺-type semiconductor regions 12) of the n-channel type MISFET Qn and the p-channel type MISFET Qp, in order to reduce the contact resistance between them and plugs 26 respectively embedded in contact holes 35, 36, 37, and 38 above the sources and drains.

A silicon nitride film 16 is formed above the gate electrode 8A (word line WL) (e.g., above the silicon layer 9 covering the W layer 29) and on the side walls thereof. The silicon nitride layer 9 and the silicon nitride film 16 are used to form contact holes 22 and 23 above the source and drain (n-type semiconductor regions 10) of the memory cell selection MISFET Qs by self-alignment with respect to the gate electrode 8A (word line WL). Note that such a silicide layer 17 as described above is not formed on the surface of the source or drain of the memory cell selection MISFET Qs.

Although not shown in the figure, peripheral circuits such as sense amplifier circuits, column decoder circuits, column driver circuits, row decoder circuits, row driver circuits, and the like are formed in regions adjacent to the memory array of the DRAM. These peripheral circuits are constructed by n-channel type MISFETs and p-channel type MISFETs which have substantially same structures as those of the n-channel type MISFETs On and p-channel type MISFET5 Op which construct the logic LSI. That is, the gate electrodes of the MISFETs constructing these peripheral circuits are each formed of a SiGe layer 28 and a W layer 29 formed thereon (directly or with a barrier layer inserted therebetween). In addition, the sources and drains thereof are each formed in the LDD structure, and a silicide layer 17 is formed on the surfaces thereof.

A silicon oxide film 20 is formed as an upper layer above the memory cell selection MISFET Os, the n-channel type MISFET On, and p-channel type MISFET Op. The surface of this silicon oxide film 20 is flattened so as to have a substantially equal height throughout the entire area of the semiconductor substrate 1.

Contact holes 22 and 23 are formed in the silicon oxide film 20 above the pair of n-type semiconductor regions 10 which construct the source and drain of the memory cell selection MISFET Os. Plugs 24 are made of a polycrystal silicon film having a low resistance and doped with n-type impurities such as phosphorus, and are embedded in the contact holes 22 and 23. As will be described later, the contact holes 22 and 23 are formed by self-alignment with respect to the gate electrodes 8A, in order to eliminate alignment margins to the gate electrodes 8A. That is, the diameter of the bottom of each of the contact holes 22 and 23 is defined by the space between a side wall of one of two adjacent gate electrodes 8A and a side wall of the other one and is smaller than the minimum processible size.

A silicon oxide film 25 is formed as an upper layer on the silicon oxide film 20. In addition, a bit line BL of the DRAM and first layer wires 30 to 34 of the logic LSI are formed above the silicon oxide film 25. The bit line and the first layer wires 30 to 34 are made of W, for example, and are simultaneously formed through same steps, as will be described later.

The first layer wires 30 and 31 in the first region are electrically connected with the source and drain (n⁺-type semiconductor regions 11) of the n-channel type MISFET Os through contact holes 35 and 36 formed in the silicon oxide film 25 and the silicon oxide film 20 below. Also, the first layer wires 32 and 33 in the third region are electrically connected with the source and drain (p⁺-type semiconductor regions 12) of the p-channel type MISFET Qp through contact holes 37 and 38 formed in the silicon oxide film 25 and the silicon oxide film 20 below the silicon oxide film 25. Further, the first layer wire 34 in the third region is electrically connected to the gate electrode 8C of the p-channel type MISFET Op through a contact hole 39 formed in the silicon oxide film 25, the silicon oxide film 20 below the silicon oxide film 25, and the silicon nitride layer 9 below the silicon oxide film 20.

Plugs 26 constructed by layering a Co film (or Ti film), a TiN film, and a W film, in that order, from the lower side, are embedded inside the contact holes 35 and 36 connecting the n-channel type MISFET Qn with the first layer wires 30 and 31 as well as inside the contact holes 37 to 39 connecting the p-channel type MISFET Op with the first layer wires 32 to 34, respectively. As described previously, a silicide layer 17 made of Co silicide (or Ti silicide), which is created by reaction between the Co film (or Ti film) forming part of the plugs 26 and silicon forming the semiconductor substrate 1, is formed at the bottom of each of these plugs.

The bit line BL of the DRAM is electrically connected to one of the source and drain (n-type semiconductor regions 10) of the memory cell selection MISFET Os through the contact hole 27 formed in the silicon oxide film 25 and the contact hole 22 formed thereunder. For example, a plug 26 formed by layering a Co film (or Ti film), TIN film, and a W film, in that order, from the lower side, is embedded inside the through hole 27. A silicide layer 17 made of Co silicide (or Ti silicide), which is created by reaction between a Co film (or Ti film) forming part of the plug 26 and polycrystal silicon forming the plug 24, is formed at the interface between this plug 26 and the contact hole 22 thereunder.

As an upper layer of the bit line BL and the first layer wires 30 to 34, a silicon oxide film 40 is formed, and a silicon oxide film 42 having great thickness is further formed as an upper layer of the silicon oxide film 40 in the first and second regions. In addition, a silicon nitride film 41 is formed as an upper layer of the silicon oxide film 40 in the first region, and a silicon oxide film 42 having great thickness is further formed as an upper layer of the silicon nitride film 41, in the first region, and as an upper layer of the silicon oxide film 40 in the second and third regions.

A deep groove 43 is formed in the silicon oxide film 42 and the silicon nitride film 41 in the first region, and an information storage capacitor element forming another part of the memory cell of the DRAM is formed inside the groove. The information storage capacitor element C is constructed in a stacked structure formed by layering a lower electrode 46, a capacitor insulating film 47, and an upper electrode 48, in that order, from the lower side.

The lower electrode 46 of the information storage capacitor element C, described above, is formed of a polycrystal silicon film having a low resistance and doped with n-type impurities such as phosphorus or the like. On the surface of this lower electrode 46, fine concave and convex portions are provided so that the surface area is enlarged to maintain the storage charge amount of the information storage capacitor element C.

The lower electrode 46 is electrically connected to the other one (that is not connected with the bit line BL) of the source and drain (n-type semiconductor regions 10) through a through hole 44 penetrating through the silicon nitride film 41, silicon oxide films 40, 25, and 20 formed thereunder and through a contact hole 23, formed under the through hole 44. A plug 45, formed of a polycrystal silicon film having a low resistance and doped with n-type impurities such as phosphorus or the like, is embedded inside the through hole 44.

The capacitor insulating film 47, layered above the lower electrode 46, is formed of a high ferroelectric film such as a tantalum oxide film or the like in order to maintain the storage charge amount of the information storage capacitor element, and the film thickness thereof is small (for example, 20 nm or so). In addition, the upper electrode 48, layered above the capacitance insulating film 47, is formed of a TiN film, for example, and covers widely the entire area of the memory array.

A silicon oxide film 50 is formed as an upper layer of the information storage capacitor element C, and a second layer wire 51 for the DRAM and second layer wires 52 and 53 for the logic LSI are formed above the film 50. These second layer wires 51 to 53 are formed of a conductive film mainly made of, for example, Al (aluminum).

The second layer wire 52 of the logic LSI is electrically connected to the first layer wire 30 through a through hole 54 which penetrates the silicon oxide film 50 and silicon oxide films 42 and 40, thereunder. In addition, the second layer wire 53 is electrically connected to the first layer wire 34 through a through hole 55 which penetrates through the silicon oxide film 50 and the silicon oxide films 42 and 40, thereunder. Plugs 56 formed by layering a Ti film, a TiN film, and a W film, in that order, from the lower side, are embedded inside the through holes 54 and 55. The second layer wire 51 of the DRAM is electrically connected to the word line WL through a through hole formed in a region, not shown.

A silicon oxide film 57 is formed as an upper layer of the wires 51 to 53 in the second layer, and a third layer wire 58 of the DRAM and a third layer wire 59 of the logic LSI are formed above the film 57. These third layer wires 58 and 59 are formed of a conductive film mainly made of Al, for example, like the second layer wires 51 to 53.

The third layer wire 58 of the DRAM is electrically connected to the upper electrode of the information storage capacitor element C through a through hole 60 penetrating the silicon oxide film 57. In addition, the third layer wire 59 of the logic LSI is electrically connected to the second layer wire 53 through the through hole 61 penetrating the silicon oxide film 57. Plugs 62 formed by layering a Ti film, a TiN film, and a W film, in that order, from the lower side, are embedded inside the through holes 60 and 61, respectively.

A passivation film (or surface protect film) made of a layer film which comprises, for example, a silicon oxide film and a silicon nitride film is formed as an upper layer on the third layer wires 58 and 59, although it is omitted from the figure.

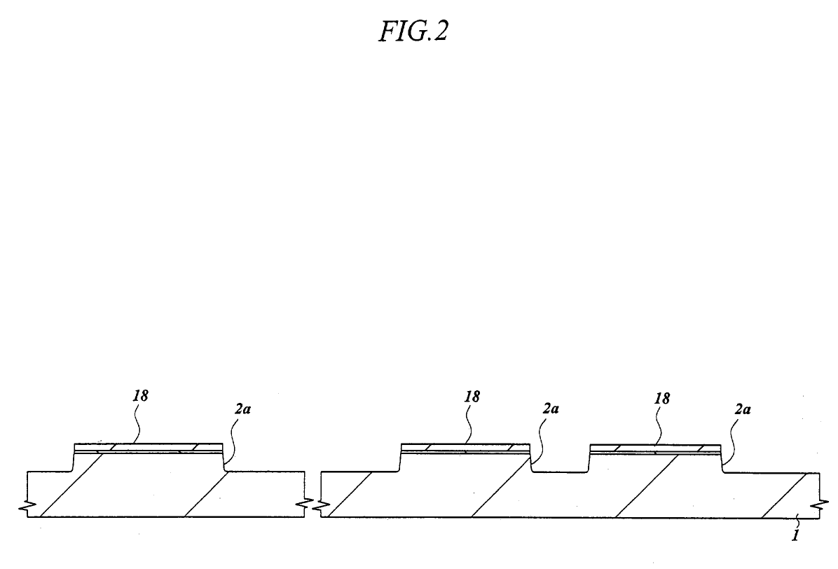

Next, an example of the method of manufacturing a DRAM-Logic mixed LSI constructed as described above will be explained with reference to FIGS. 2 to 24.

At first, as shown in FIG. 2, a groove 2a having a depth of 300 to 400 nm is formed in the main surface of the semiconductor substrate 1. This groove 2a is formed by covering an element-forming region of the semiconductor substrate 1 with a silicon nitride film 18 and by thereafter dry-etching the semiconductor substrate 1 at an element separation region with the silicon nitride film 18 used as a mask.

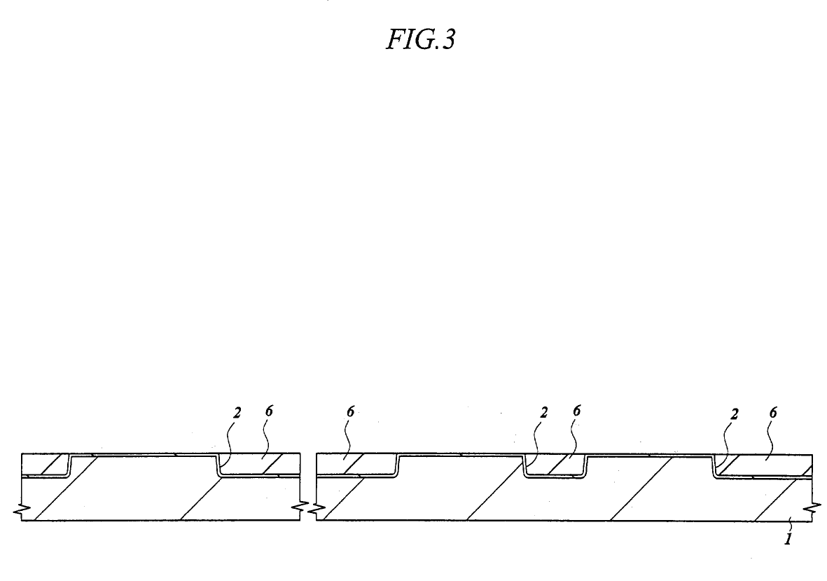

Next, as shown in FIG. 3, a silicon oxide film 6 having film thickness of about 600 nm is deposited on the semiconductor substrate 1, including the inside of the groove 2a, by a CVD (Chemical Vapor Deposition) method, and is thereafter polished by a CMP (Chemical Mechanical Polishing) method, with this film remaining only inside the groove 2a. Thus, an element separation groove 2 is formed in the element separation region of the semiconductor substrate 1.

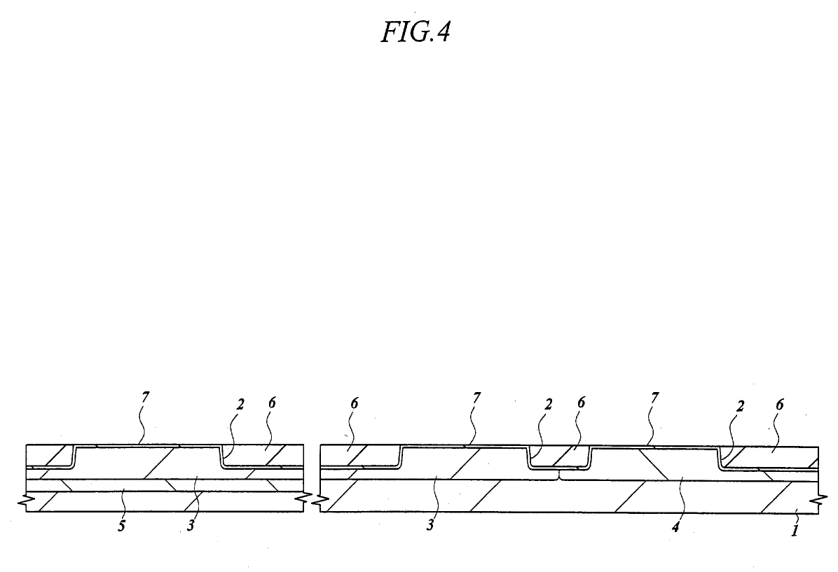

Next, as shown in FIG. 4, p-type impurities (boron) are ion-implanted into the second region (which is the n-channel type MISFET forming region of the logic LSI) of the semiconductor substrate 1, thereby to form a p-type well 3, and n-type impurities (phosphorus) are ion-implanted into the third region (which is the p-channel type MISFET forming region of the logic LSI), thereby to form an n-type well 4. In addition, n-type impurities (phosphorus) and p-type impurities (boron) are ion-implanted into the first region (which is the memory array forming region of the DRAM), thereby to form a p-type well 3 at a shallow region of the semiconductor substrate 1 as well as an n-type well 5 at a deep region thereof.

At this time, p-type impurities (e.g., boron) for controlling the threshold voltage of the memory cell selection MISFET Qs are ion-implanted into the first region of the semiconductor substrate 1, p-type impurities (boron) for controlling the threshold voltage of n-channel type MISFET Qn are ion-implanted into the second region, and n-type impurities (phosphorus) for controlling the threshold voltage of the p-channel type MISFET Qp are ion-implanted into the third region.

Subsequently, the surface of each of the p-type well 3 and the n-type well 4 is washed with use of a HF-based (hydrofluoric-acid-based) washing solution, and thereafter, the semiconductor substrate 1 is subjected to wet oxidation at about 850° C., thereby to form a clean gate insulating film 7 made of silicon oxide on each of the surfaces of the p-type well, 3 and n-type well 4.

The gate insulating film 7 may be formed of a silicon oxynitride film in place of a silicon oxide film. That is, if the film thickness of the gate insulating film 7 is made thinner, a part of impurities (boron) in the SiGe layer 28 forming part of the gate electrodes 8A, 8B, and 8C is diffused into the semiconductor substrate 1 through the gate insulating film 7 by a heat treatment in the process, so that the threshold voltage easily changes. The silicon oxynitride film less easily allows impurities to pass than a silicon oxide film. Therefore, changes of the threshold voltage can be restricted by forming the gate insulating film 7 from an oxynitride silicon film. In addition, the silicon oxynitride film is more capable of restricting the generation of interface levels in the film and reducing electronic traps than the silicon oxide film. Therefore, the hot carrier tolerance of the gate insulating film 7 can be improved. To form a silicon oxynitride film, the semiconductor substrate may be subjected to a heat treatment in an atmosphere of a gas containing nitrogen, such as NO, NO₃, or NH₃, for example.

Also, the same effect as described above can be attained if the semiconductor substrate 1 is subjected to a heat treatment in an atmosphere of a gas containing nitrogen as described above thereby to segregate nitrogen at the interface between the gate insulating film 7 and the semiconductor substrate 1, after a gate insulating film 7 made of silicon oxide is formed on the surface of each of the p-type well 3 and n-type well 4.

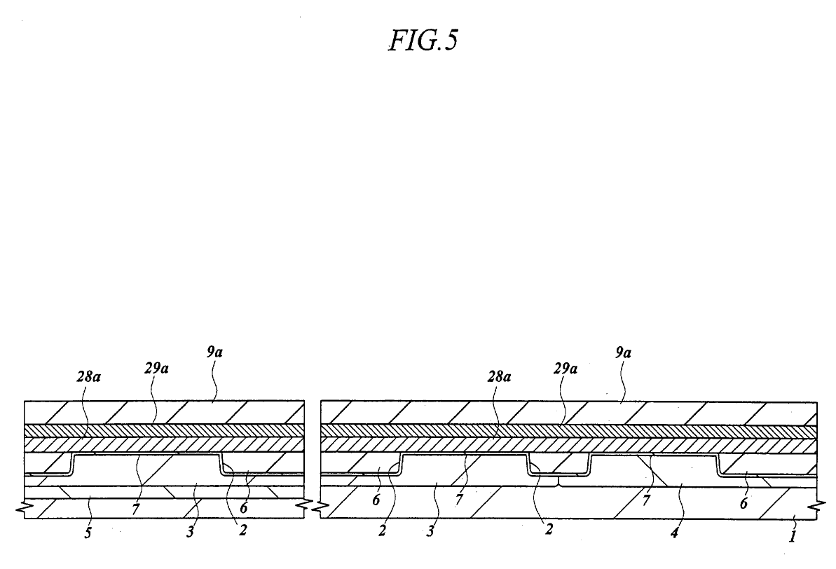

Next, as shown in FIG. 5, a SiGe film 28a having film thickness of about 100 nm is deposited on the semiconductor substrate 1 by a CVD method, and subsequently, a W film 29a having film thickness of about 100 nm is deposited on the SiGe film 28a by a sputtering method. Thereafter, a silicon nitride film 9a having thickness of about 200 nm is deposited on the W film 29a. Upon requirements, a TiN film or a WN film which forms a barrier layer may be deposited thinly between the SiGe film 28a and the W film 29a.

The SiGe film 28a is deposited by a CVD method in which silane (SiH₄), germane (GeH₄), and diborane (B₂H₆) are used for a source gas and the conductivity type is set to p-type, so that the work functions of the gate electrodes 8A, 8B, and 8C become substantially midway between those of n-type polycrystal silicon and p-type polycrystal silicon. If the work functions of the gate electrodes 8A, 8B, and 8C should be set offset from the middle between the work functions of n-type polycrystal silicon and p-type polycrystal silicon due to reasons from the design specifications, the conductivity type may be set to n-type.

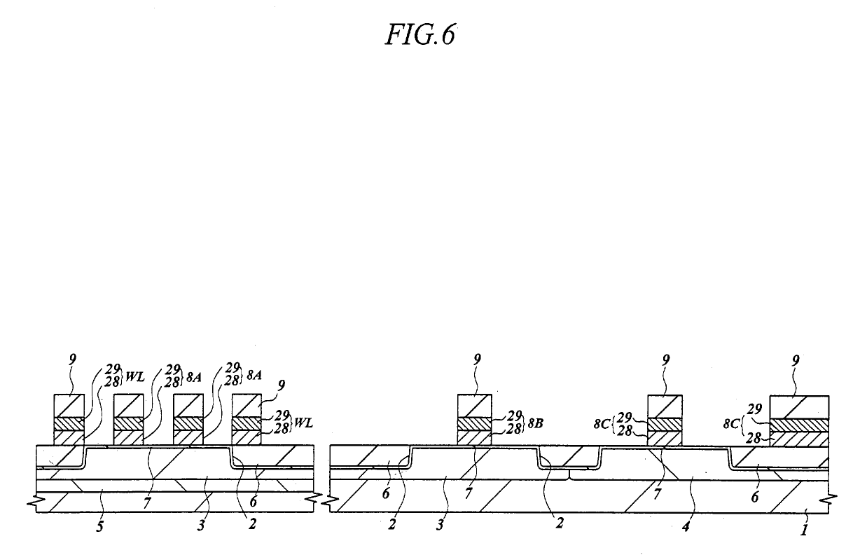

Next, as shown in FIG. 6, the silicon nitride film 9a, the W film 29a, and the SiGe film 28a are subjected to dry etching with a photoresist film used as a mask, thereby to form a gate electrode 8A (word line WL) of the memory cell selection MISFET Qs, a gate electrode 8B of the n-channel type MISFET Qn, and a gate electrode 8C of the p-channel type MISFET Qp, each having a two-layer structure consisting of the SiGe layer 28 and the W layer 29.

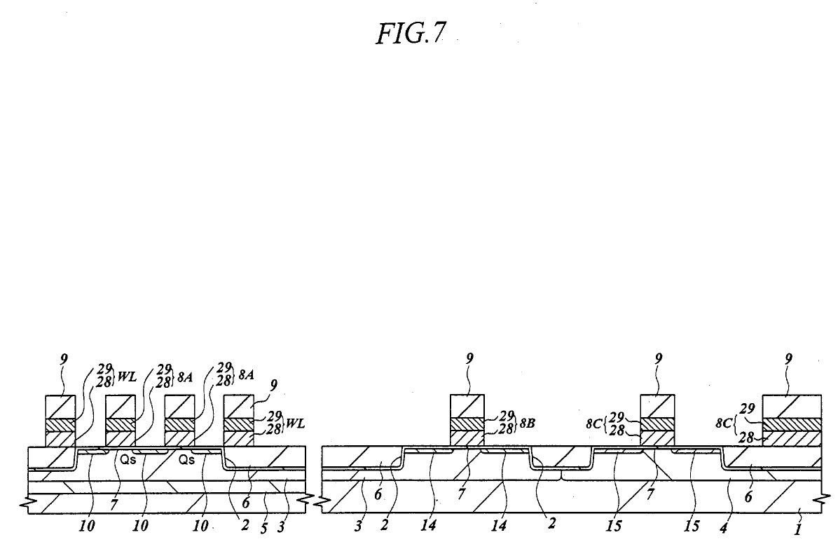

Next, as shown in FIG. 7, n-type impurities (phosphorus or arsenic) are ion-implanted into the p-type well 3 in the first and second regions, thereby to form n-type semiconductor regions 10 forming the source and drain of the memory cell selection MISFET Qs in the p-type well 3 in the first region as well as an n-type semiconductor region 14 in the p-type well 3 in the second region. Subsequently, p-type impurities (boron) are ion-implanted into the n-type well 4 in the third region thereby to form p-type semiconductor regions 15. Through the steps described above, the memory cell selection MISFET Qs of the DRAM is substantially completed.

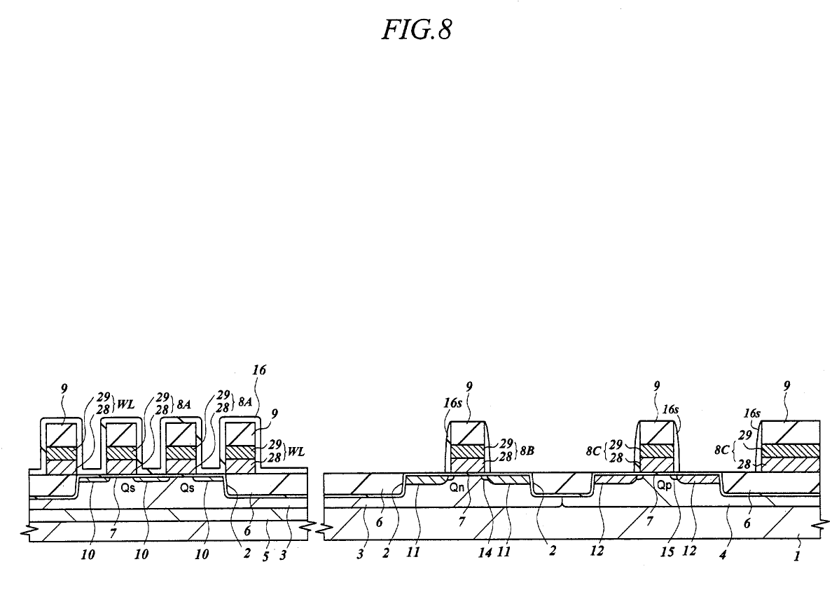

Next, as shown in FIG. 8, a silicon nitride film 16 having film thickness of about 50 to 100 nm is deposited on the semiconductor substrate 1 by a CVD method, and thereafter, the silicon nitride film 16 in the first region is covered with a photoresist film (not shown). The silicon nitride film in the second and third regions is anisotropically etched, thereby to form side wall spacers on the side walls of the gate electrodes 8B and 8C.

Subsequently, n-type impurities (phosphorus) are ion-implanted into the p-type well 3 in the second region thereby to form n⁺-type semiconductor regions 11 (source and drain) having a high impurity density, and p-type impurities (boron) are ion-implanted into the n-type well 4 in the third region thereby to form p⁺-type semiconductor regions 12 (source and drain) having a high impurity density. Through the steps up to this stage, the n-channel type MISFET Qn and the p-channel type MISFET Qp with sources and drains of the LDD structure are substantially completed.

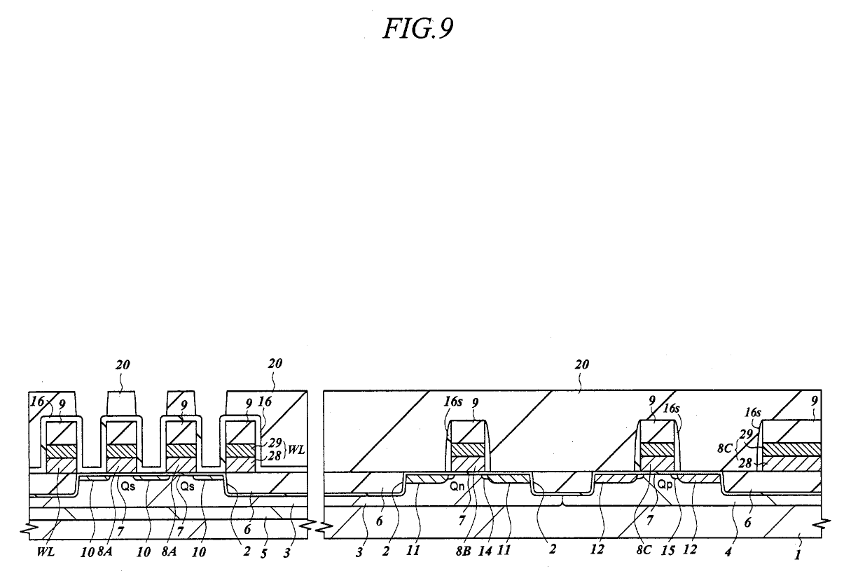

Next, as shown in FIG. 9, a silicon oxide film 20 having film thickness of 600 nm is deposited on the semiconductor substrate 1 by a CVD method, and subsequently, the silicon oxide film 20 is polished by a CMP method to flatten its surface. Thereafter, with a photoresist film used as a mask, the silicon oxide film 20 above the source and drain (n-type semiconductor regions 10) of the memory cell selection MISFET Qs is subjected to dry etching. This etching is carried out with use of a gas (e.g., C₄F₈+Ar) which etches the silicon oxide film 20 at a high selection ratio, in order to prevent the silicon nitride film 16 as a lower layer of the silicon oxide film 20 from being etched.

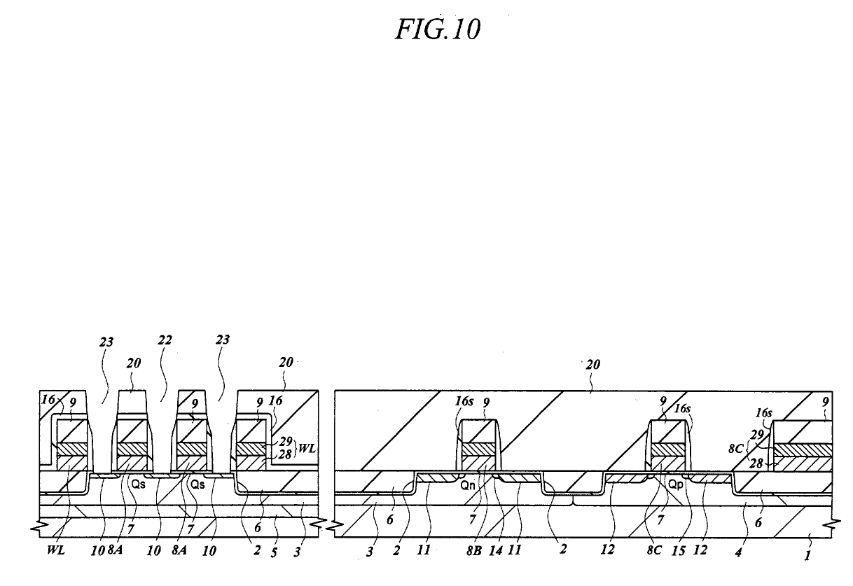

Next, as shown in FIG. 10, the silicon nitride film 16 above the source and drain (n-type semiconductor regions 10) of the memory cell selection MISFET Qs is subjected to dry etching, thereby to form a contact hole above one of the source and drain (n-type semiconductor regions 10) and a contact hole 23 above the other of the source and drain. This etching is carried out with a gas (CF₄+CHF₃+Ar) which etches the silicon nitride film 16 with a high selection ratio, in order to minimize the etching amounts of the semiconductor substrate 1 and the silicon oxide film 6 in the element separation groove 2. In addition, this etching is performed under condition that the silicon nitride film 16 is etched anisotropically, such that the silicon nitride film 16 remains on the side walls of the gate electrode 8A (word lines WL). As a result, contact holes 22 and 23 each having a smaller diameter than a space between adjacent gate electrodes 8A (word lines WL) are formed by self-alignment with respect to the gate electrodes 8A (word lines WL).

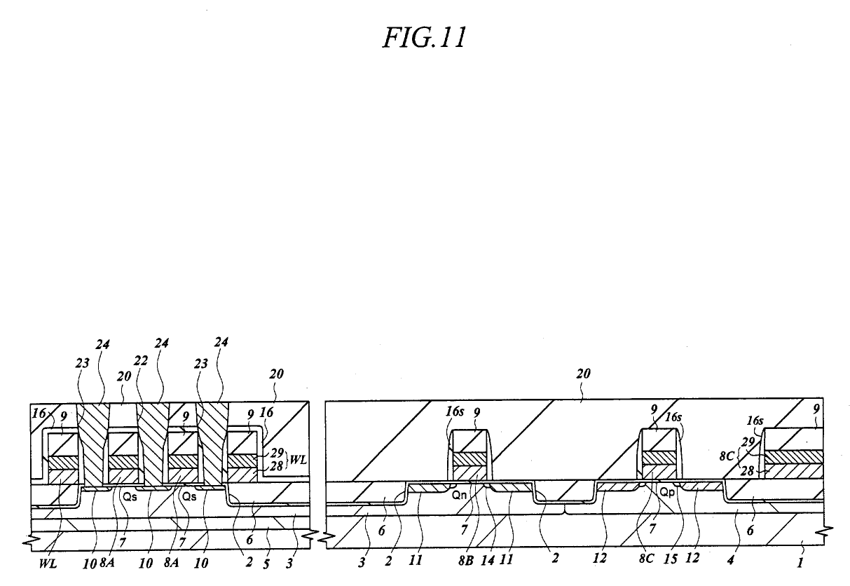

Next, as shown in FIG. 11, plugs 24 are formed in the contact holes 22 and 23 described above. The plugs 24 are formed by depositing a polycrystal silicon film doped with n-type impurities (phosphorus) on the silicon oxide film 20 including the insides of the contact holes 22 and 23 and by thereafter etching back the polycrystal silicon film such that the polycrystal silicon film remains only inside the contact holes 22 and 23.

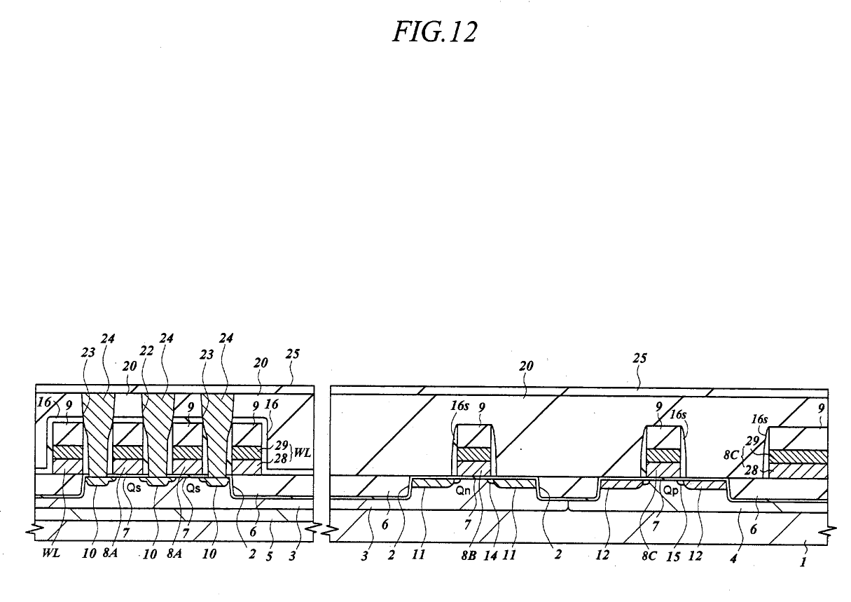

Next, as shown in FIG. 12, a silicon oxide film 25 having thickness of about 200 nm is deposited above the silicon oxide film 20, and thereafter, the semiconductor substrate 1 is subjected to a heat treatment in an inactive gas atmosphere. By this heat treatment, n-type impurities in the polycrystal silicon film forming the plugs 24 in the contact holes 22 and 23 are diffused into the n-type semiconductor regions 10 (source and drain) of the memory cell selection MISFET Qs, thereby to lower the resistance of the n-type semiconductor regions 10.

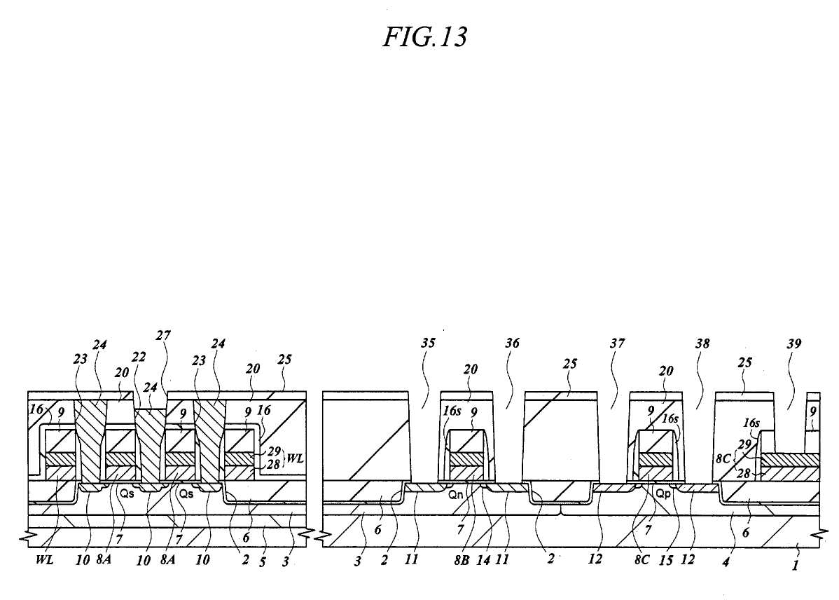

Next, as shown in FIG. 13, the silicon oxide film 25 in the first region is subjected to dry etching with a photoresist film used as a mask, thereby to form a through hole 27 above the contact hole 22. Subsequently, the silicon oxide film 25 in the second region and the silicon oxide film 20 thereunder are subjected to dry etching thereby to form contact holes 35 and 36 above the source and drain (n⁺-type semiconductor regions 11) of the n-channel type MISFET Qn, and the silicon oxide film 25 in the third region, the silicon oxide film 20 thereunder, and the silicon nitride layer 9 above the gate electrode 8C are subjected to dry etching, thereby to form contact holes 37 and 38 above the source and drain (p-type semiconductor regions 12) of the p-channel type MISFET Qp as well as a contact hole 39 above the gate electrode 8C.

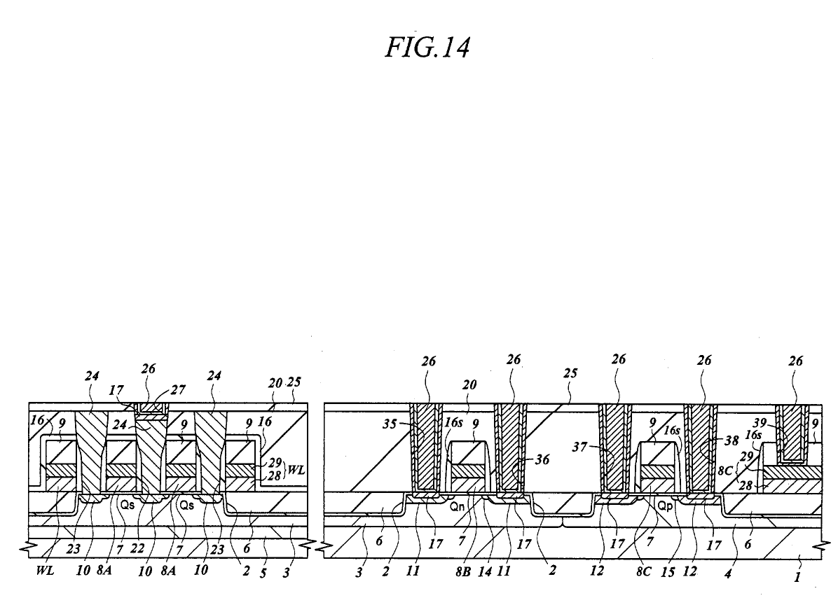

Next, as shown in FIG. 14, a silicide layer 17 is formed on the surfaces of the source and drain (n⁺-type semiconductor regions 11) of the n-channel type MISFET Qn, on the surfaces of the source and drain (p⁺-type semiconductor regions 12) of the p-channel type MISFET Qp, and on the surface of the plug 24 formed inside the contact hole 22. Thereafter, plugs 26 are formed inside the contact holes 35 to 39 and the through hole 27.

The silicide layer 17 is formed by depositing a Co film (or Ti film) above the silicon oxide film 25 including the insides of the contact holes 35 to 39 and the through hole 27 by a sputtering method and by thereafter subjecting the semiconductor substrate 1 to a heat treatment. In addition, the plugs 26 are formed by depositing a TiN film and a W film above the Co film (or Ti film) including the insides of the contact holes 35 to 39 and the through hole 27 by a CVD method and by thereafter polishing the W film, TiN film, and Co film (or Ti film) above the silicon oxide film 25 by a CMP method such that these films remain only inside the contact holes 35 to 39 and the through hole 27.

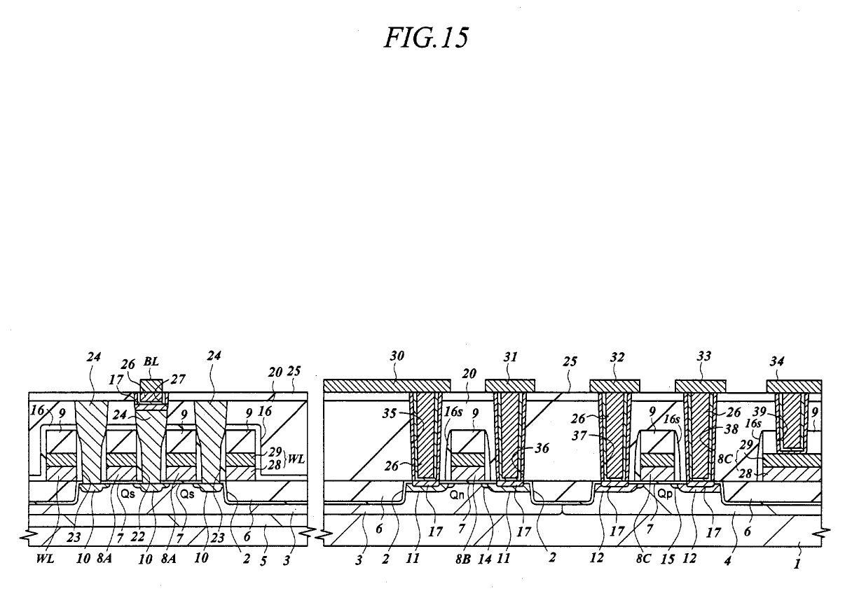

Next, as shown in FIG. 15, a bit line BL of the DRAM and first layer wires 30 to 34 of the logic LSI are formed above the silicon oxide film 25. The bit line BL and the first layer wires 30 to 34 are formed by depositing a W film with thickness of about 200 nm above the silicon oxide film 25 by a sputtering method and by thereafter dry etching the W film with a photoresist film used as a mask.

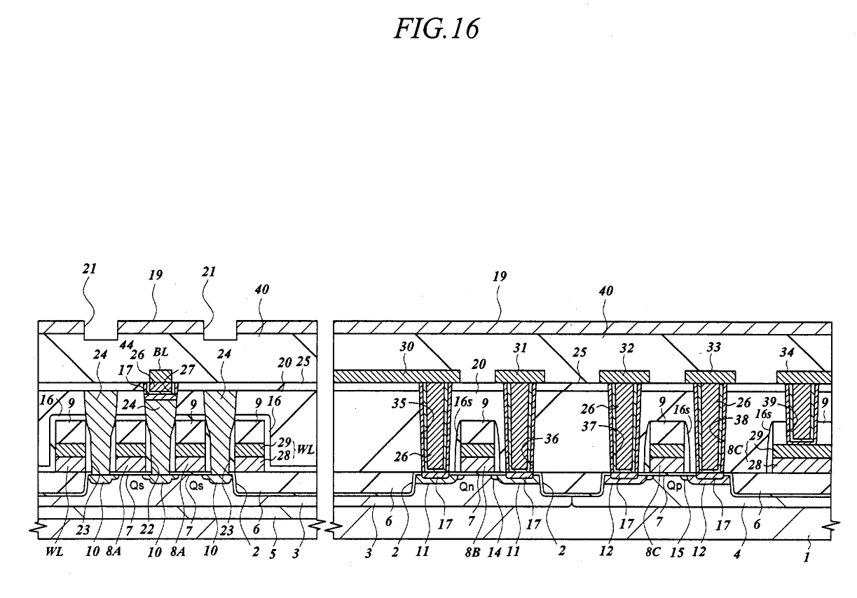

Next, as shown in FIG. 16, a silicon oxide film 40 having film thickness of about 300 nm is deposited above the bit line BL and the first layer wires 30 to 34 by a CVD method, and, subsequently, a polycrystal silicon film 19 having film thickness of about 200 nm is deposited above the silicon oxide film 40. Thereafter, the polycrystal silicon film 19 in the first region is subjected to dry etching with a photoresist film used as a mask, thereby to form grooves 21 in the polycrystal silicon film 19 above the contact holes 23, each of the grooves 21 having a diameter equivalent to the minimum processible size of lithography.

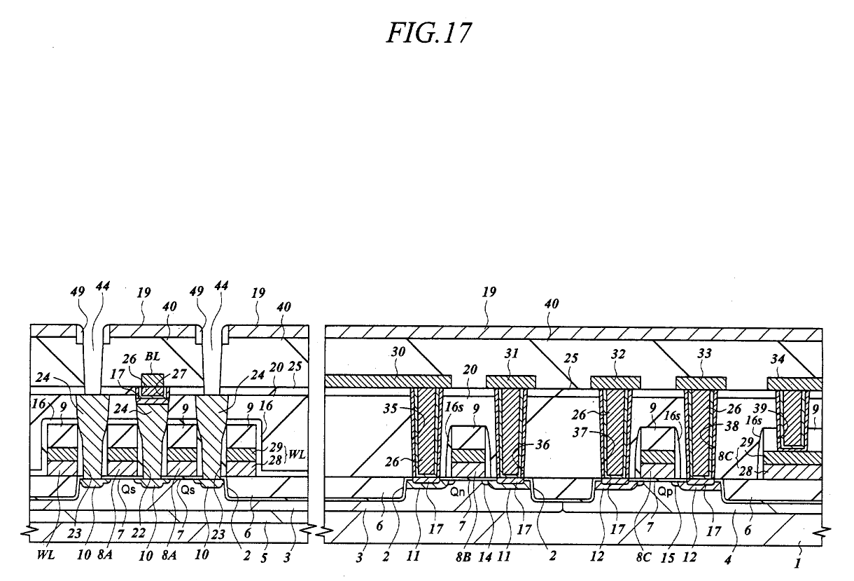

Next, as shown in FIG. 17, side wall spacers 49 are formed on the side walls of the grooves 21 in the polycrystal silicon film 19, and, thereafter, the silicon oxide film 40 and the silicon oxide film 25 thereunder are subjected to dry etching with the polycrystal silicon film 19 and the side wall spacers 49 used as masks, thereby to form through holes 44 above the contact holes 23. The side wall spacers 49 on the side walls of the grooves 21 are formed by depositing a polycrystal silicon film above the polycrystal silicon film 19 including insides of the grooves 21 by a CVD method and by thereafter anisotropically etching the polycrystal silicon film such that this film remains on the side walls of the grooves 21. By forming the side wall spacers 49 as described above on the side walls of the grooves 21, the through holes 44 formed above the contact holes 23 each have a diameter equal to or smaller than the minimum processible size of lithography.

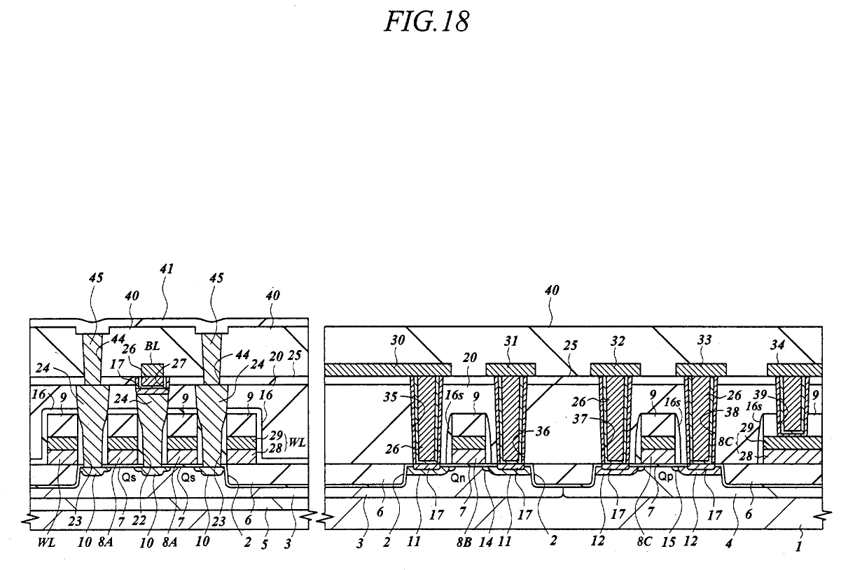

Next, as shown in FIG. 18, plugs 45 are formed inside the through holes 44, and thereafter, a silicon nitride film 41 having film thickness of about 100 nm is deposited on the silicon oxide film 40 by a CVD method. Subsequently, the silicon nitride film 41 in the second and third regions is removed by etching with a photoresist film used as a mask. The plugs 45 are formed by depositing a polycrystal silicon film doped with n-type impurities (phosphorus) above the silicon oxide film 40 including the insides of the through holes 44 and by thereafter etching back the polycrystal silicon film such that this film remains only inside the through holes 44. The silicon nitride film 41 remaining on the silicon oxide film 40 in the first region is used as an etching stopper when dry-etching a silicon oxide film 42 which will be deposited on the silicon nitride film 41 in a step described later.

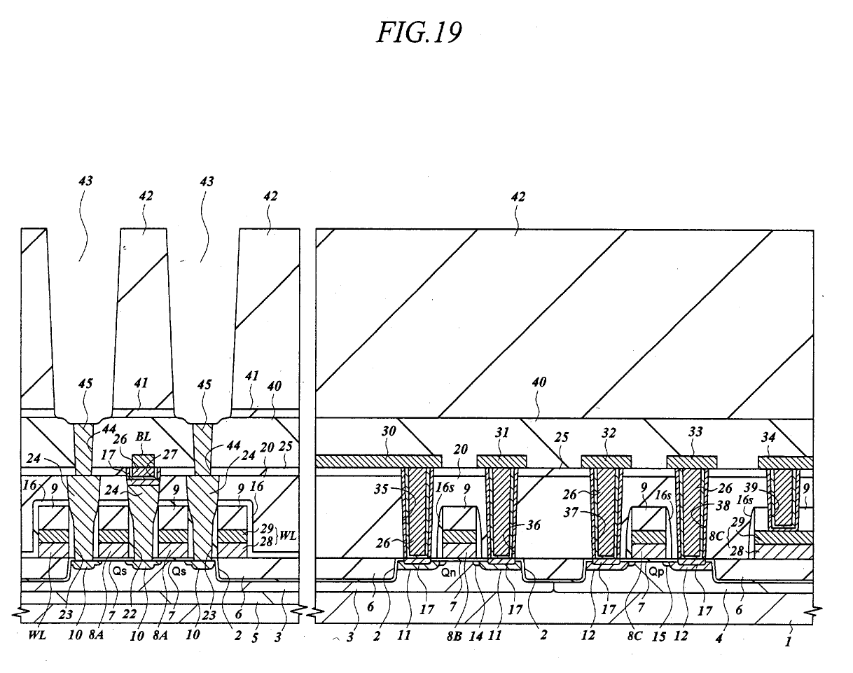

Next, as shown in FIG. 19, a silicon oxide film 42 is deposited above the silicon nitride film 41 in the first region and above the silicon oxide film 40 in the second and third regions. Thereafter, the silicon oxide film 40 in the first region is subjected to dry etching with a photoresist film used as a mask, and, subsequently, the silicon nitride film 41, as an upper layer of the silicon oxide film 40, is subjected to dry etching, thereby to form grooves 43 above the through holes 44.

Since lower electrodes 46 of the information storage capacitor element C are formed along the inner walls of the grooves 43, the silicon oxide film 42 must be deposited with large thickness (e.g., about 1.3 μm) so that the grooves 43 become deep, in order to enlarge the surface areas of the lower electrodes to increase the storage charge amount.

In addition, grooves 43 are formed in the silicon oxide film having large film thickness and deposited on the entire surface (including the first to third regions) of the semiconductor substrate 1, and forming information storage capacitor elements C inside the grooves. As a result, the surface of a silicon oxide film 50 which will be deposited as an upper layer of the information storage capacitor elements C is set to a substantially equal height in the first region where the memory array of the DRAM is formed and in the second and third regions where the logic LSI is formed. In this manner, the gaps of the subbing layer of the second layer wires 51 to 53 which will be formed above the silicon oxide film 50 are reduced so that the reliability of the second layer wires 51 to 53 is improved.

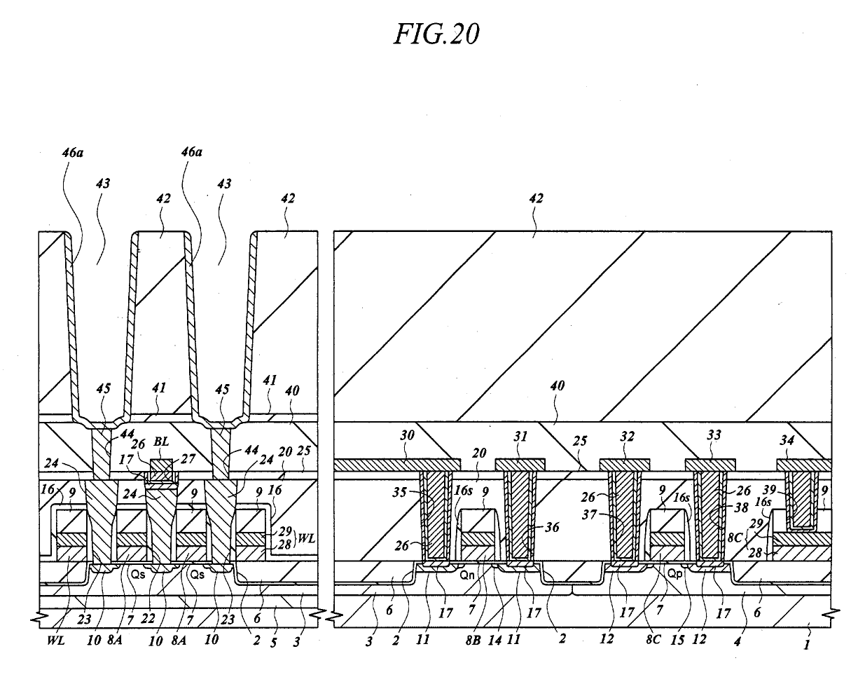

Next, as shown in FIG. 20, an amorphous silicon film 46a having film thickness of 50 nm and doped with n-type impurities (phosphorus) is deposited by a CVD method above the silicon oxide film 42 including the insides of the grooves 43, and, thereafter, the amorphous silicon film 46a above the silicon oxide film 42 is etched back and removed so that the amorphous silicon film 46a remains along the inner walls of the grooves 43.

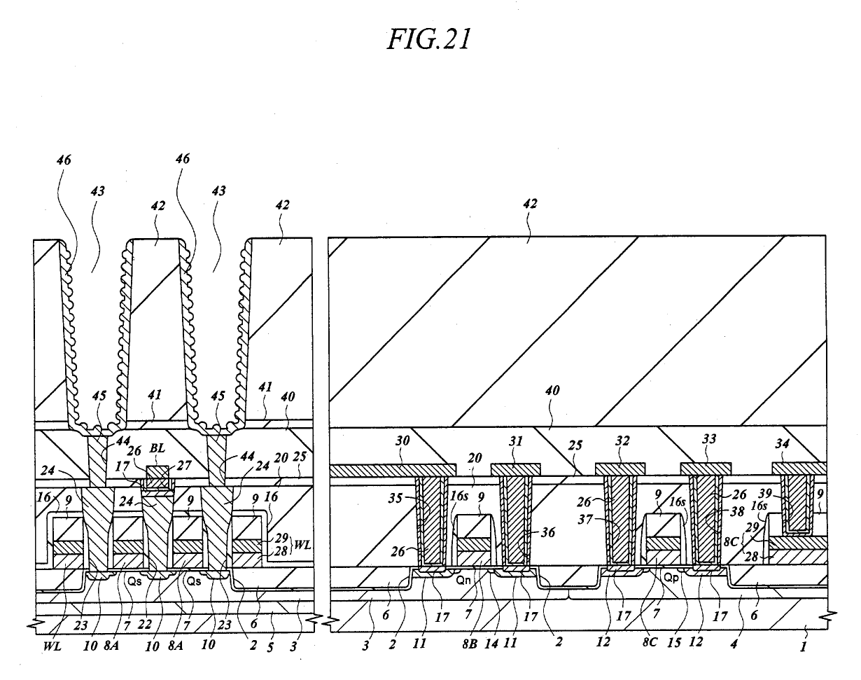

Subsequently, the surface of the amorphous silicon film 46a remaining inside the grooves 43 is washed with a hydrofluoric-acid-based etching solution, and monosilane (SiH₄) is supplied to the surface of the amorphous silicon film 46a in an atmosphere under a reduced pressure. Subsequently, the semiconductor substrate 1 is subjected to a heat treatment to poly-crystallize the amorphous silicon film 46a, and then silicon grains are grown on its surface. In this manner, as shown in FIG. 21, lower electrodes made of a polycrystal silicon film having a roughed surface are formed along the inner walls of the grooves 43.

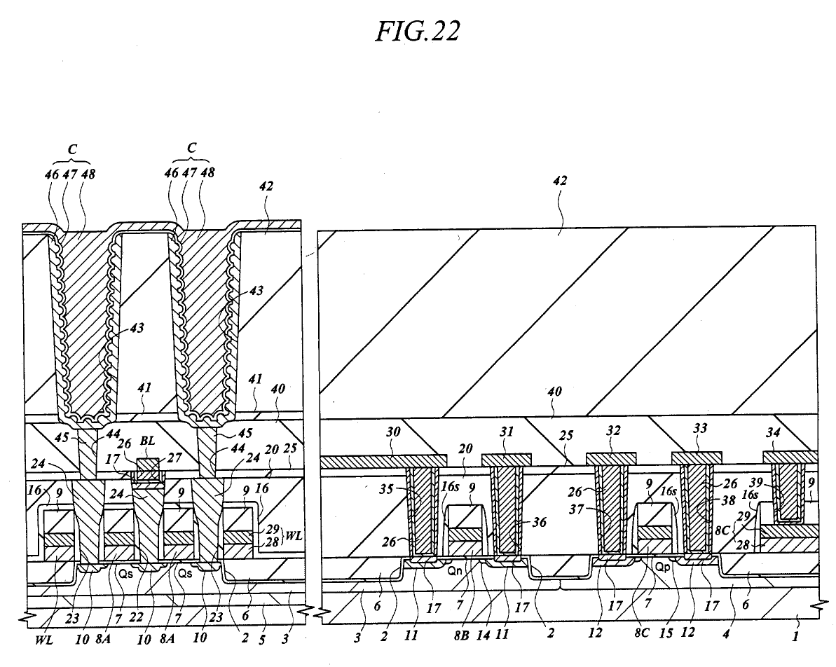

Next, as shown in FIG. 22, a capacitor insulating film 47 made of a tantalum oxide film and an upper electrode 48 made of a TIN film are formed above the lower electrodes 46. The capacitor insulating film 47 and the upper electrode 48 are formed by firstly depositing a tantalum oxide film having film thickness of about 20 nm above the silicon oxide film 42 including the insides of the grooves 43, and by subsequently depositing a TIN film having film thickness of about 150 nm to fill the insides of the grooves 43 with the TiN film, by a CVD method and a sputtering method. Thereafter, the TIN film and the tantalum oxide film are subjected to dry etching with a photoresist film used as a mask. In this manner, the information storage capacitor element C comprising the lower electrodes 46 formed of a polycrystal silicon film, the capacitor insulating film 47 made of a tantalum oxide film, and the upper electrode 48 made of a TIN film is formed. In addition, through the steps up to this stage, memory cells comprising memory cell selection MISFETs Qs and information storage capacitor elements C connected in series thereto are completed.

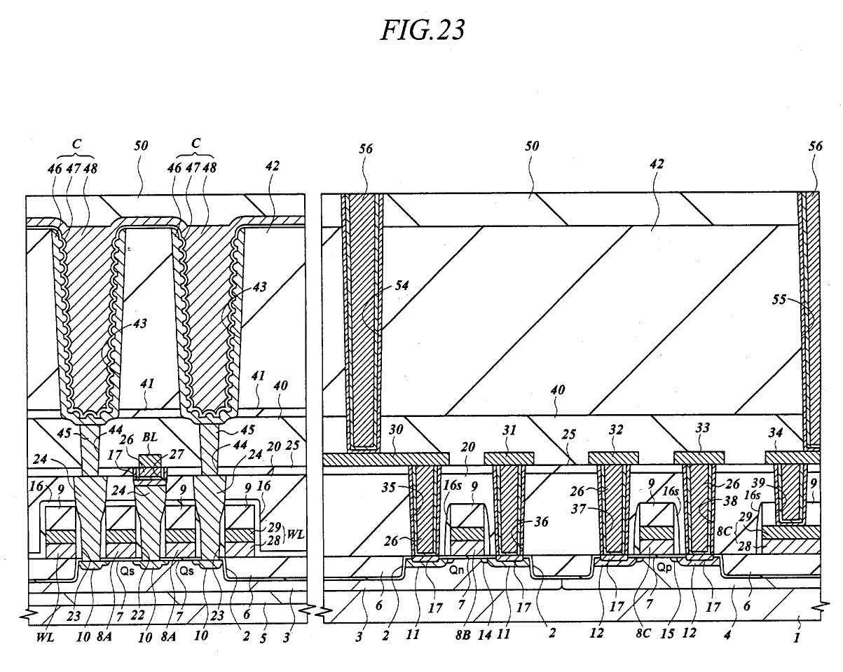

Next, as shown in FIG. 23, a silicon oxide film 50 having film thickness of-about 200 nm is deposited by a CVD method as an upper layer of the information storage capacitor elements C, and, thereafter, the silicon film 50 in the second and third regions and the silicon oxide films 42 and 40 thereunder are subjected to dry etching with a photoresist film used as a mask, thereby to form a through hole 54 above the first layer wire 30 as well as to form a through hole 55 above the first layer wire 34.

Subsequently, plugs 56 are formed inside the through holes 54 and 55. The plugs 56 are formed such as by depositing a Ti film having film thickness of about 10 nm on the silicon oxide film 50 including the insides of the through holes 54 and 55 by a sputtering method, subsequently depositing a TiN film having film thickness of about 100 nm and a W film having film thickness of about 500 nm thereon by a CVD method, and, thereafter, polishing these films by a CMP method such that these films remain only inside the through holes 54 and 55.

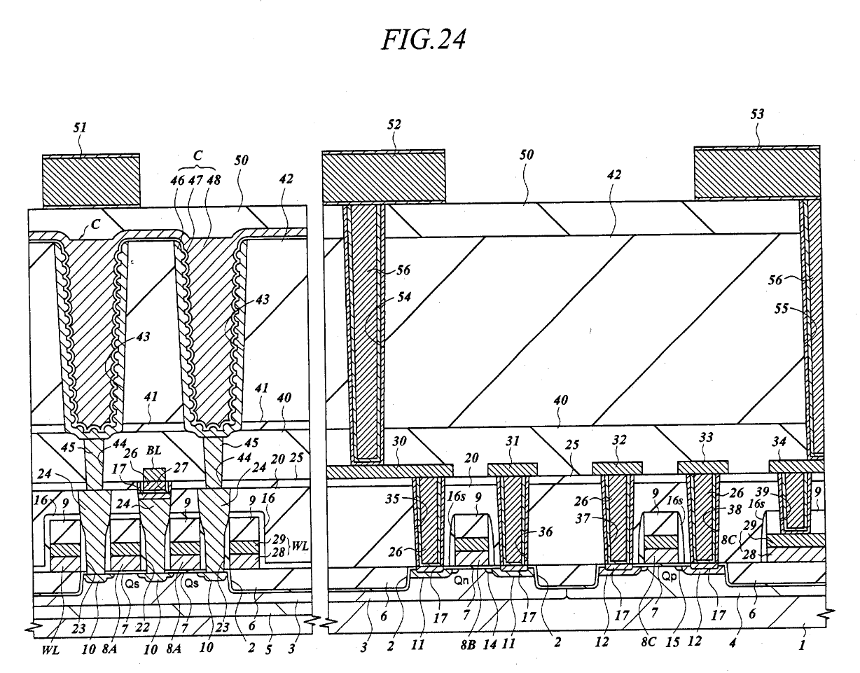

Next, as shown in FIG. 24, second layer wires 51 to 53 are formed above the silicon oxide film 50. The second layer wires 51 to 53 are formed by depositing sequentially by a sputtering method a TIN film having film thickness of 50 nm, an Al alloy film having film thickness of about 500 nm, and a Ti film having film thickness of about 10 nm above the silicon oxide film 50, and by thereafter subjecting these films to dry etching.

Thereafter, a silicon oxide film 57 is deposited above the second layer wires 51 to 53. Subsequently, a through hole 60 is formed in the silicon oxide films 57 and 52 above the information storage capacitor element C, and a through hole 61 is formed in the silicon oxide film 57 above the second layer wire 53. Thereafter, plugs 62 are formed inside these through holes 60 and 61, and further, third layer wires 58 and 59 are formed above the silicon oxide film 57. Thus, the semiconductor integrated circuit device as shown in FIG. 1 is substantially completed. The through holes 60 and 61, plugs 62, and third layer wires 58 and 59 are formed in the same manner as the through holes 54, 55, plugs 56, and third layer wires 51 to 53 are formed,

According to the present embodiment constructed in the structure as described above, the gate electrodes 8A of the memory cell selection MISFETs Qs forming the memory cells of the DRAM and the gate electrodes 8B and 8C of the n-channel type MISFET Qn and the p-channel type MISFET Qp are each formed of a SiGe layer 28 and a W layer 29 formed above layer 28 (directly or with a barrier layer inserted therebetween). Therefore, the work functions of the gate electrodes 8A, 8B, and 8C can be set to be substantially midway between the work function of n-type polycrystal silicon and that of p-type polycrystal silicon. Accordingly, drops of the threshold voltages of the MISFETs (Qs, Qn, and Qp) can be prevented without increasing the impurity density of the semiconductor substrate (e.g., the p-type well 3 and n-type well 4).

As a result of this, the difference between the threshold voltages between the three types of MISFETs (Qs, Qn, and Qp) is reduced, so that the operation for adjusting the threshold voltages can be facilitated and optimal threshold voltages can be set for the MISFETs, respectively.

In addition, since the intensity of the electric field is relaxed at end portions of the sources and drains of the memory cell selection MISFETs Qs, it is possible to avoid increases of leakage currents as well as increase of the parasitic capacitance of bit lines. Further, since the sub-threshold currents of the memory cell selection MISFETs Qs are reduced due to a decrease of the substrate density, it is possible to reduce the leakage currents. As a result of this, the refresh characteristics and the data read speed of the DRAM can be improved.

Since the gate electrodes 8B and 8C, respectively forming the n-channel type MISFET Qn and the p-channel type MISFET Qp which constitute the logic LSI, have a same conductivity type, the problem of increase of the resistance due to mutual diffusion of impurities does not occur unlike a dual gate CMOS even when these gate electrodes 8B and 8C are connected with each other.

Since the work functions of the gate electrodes 8A, 8B, and 8C are each set to be substantially midway between the work functions of n-type polycrystal silicon and p-type polycrystal silicon, the three types of the MISFETs (Qs, Qn, and Qp) each become an intermediate type between an embedded channel type and a surface channel type. It is therefore possible to obtain memory cell selection MISFETs Qs and n-channel type MISFET Qn which have higher current drive performance than in case where MISFETs are formed as a surface channel type.

The gate insulating film 7 for each of the n-channel type MISFET Qn and the p-channel type MISFET Qp forming the logic LSI can be made thinner. In addition, since the sources and drains of these MISFETs (Qn and Qp) are made of silicide, the contact resistance with respect to the plugs 26 embedded in the contact holes 35, 36, 37, and 38 above the sources and drains can be reduced. As a result of this, high-speed operation of the logic LSI can be promoted.

In addition, since the substrate bias effect due to the impurity density of the substrate is restricted, the voltage for boosting the word line can be set to be low, and the gate insulating films 7 of the memory cell selection MISFET Qs can be made thinner. As a result, the gate insulating films 7 of the three types of MISFETs (Qs, Qn, and Qp) can be formed by same steps, so that the manufacturing process of the DRAM-logic mixed LSI can be simplified.

Since the gate electrodes 8A, 8B, and 8C of the three type of MISFETs (Qs, Qn, and Qp) have a same conductivity type, steps of selectively implanting n-type impurities and p-type impurities into a gate electrode material are not required, unlike a dual gate CMOS. As a result of this, compared with a dual gate CMOS structure, the number of ion-implantation steps and the number of photomasks to be used are reduced so that the manufacturing process of the DRAM-logic mixed LSI is simplified.

Since the gate electrodes 8A, 8B, and 8C of the three type of MISFETs (Qs, Qn, and Qp) are made of the same material and have the same conductivity type, a problem of overetching the substrate including removing more in both sides of one gate electrode than in both sides of another gate electrode, when etching the gate electrode materials, does not occur, unlike that of a dual gate CMOS.

Since a silicon nitride layer 9 is layered on the gate electrodes 8A, 8B, and 8C, contact holes 22 and 23 each having a smaller diameter than the space between the adjacently disposed gate electrodes 8A (word lines WL) can be formed by self-alignment with respect to the gate electrodes 8A, and the memory cell size of the DRAM can be reduced.

(Embodiment 2)

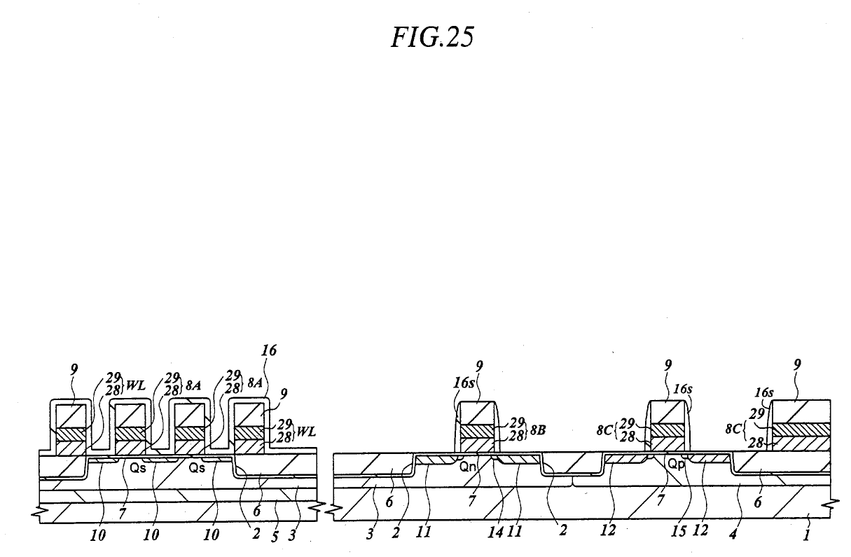

The method of manufacturing a DRAM-logic mixed LSI according to the present embodiment will be explained in the order of manufacturing steps with reference to FIGS. 25 to 27.

At first, as shown in FIG. 25, memory cell selection MISFETs Qs are formed in the first region of the semiconductor substrate 1, and an n-channel type MISFET Qn and a p-channel type MISFET Qp are respectively formed in the second and third regions. The manufacturing steps up to this stage are the same as those of the previous embodiment shown in FIGS. 2 to 8.

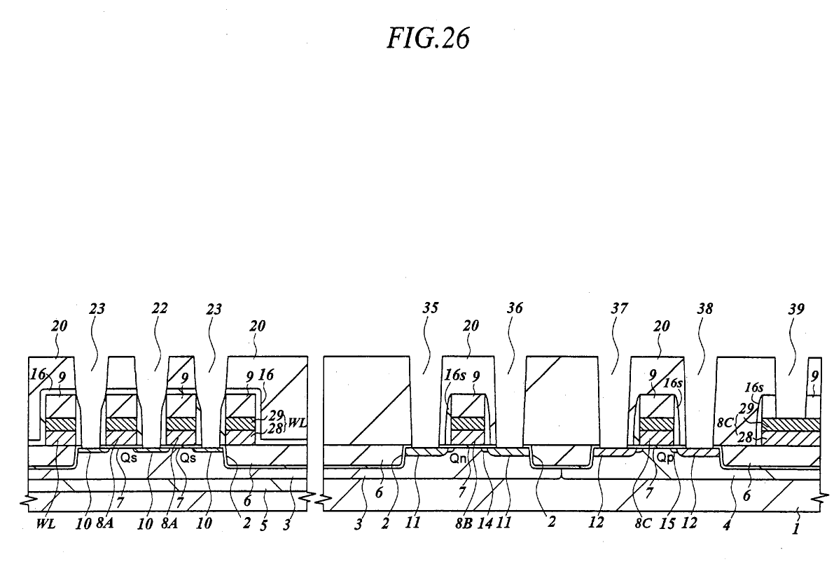

Next, as shown in FIG. 26, a silicon oxide film 20 is deposited on the semiconductor substrate 1 by a CVD method, and, thereafter, the silicon oxide film 20 is subjected to dry etching with a photoresist film used as a mask. Further, the silicon nitride film 16 and the silicon nitride layer thereunder are subjected to dry etching, thereby to form contact holes 22 and 23 above the sources and drains (n-type semiconductor regions 10) of the memory cell selection MISFET Qs, to form contact holes 35 and 36 above the source and drain (n⁺-type semiconductor regions 11) to form contact holes 37 and 38 above the source and drain (p⁺-type semiconductor regions 12) of the p-channel type MISFET Qp, and to form a contact hole 39 above the gate electrode 8C. That is, according to the present embodiment, the contact holes 22, 23, and 35 to 39 are formed simultaneously through same steps.

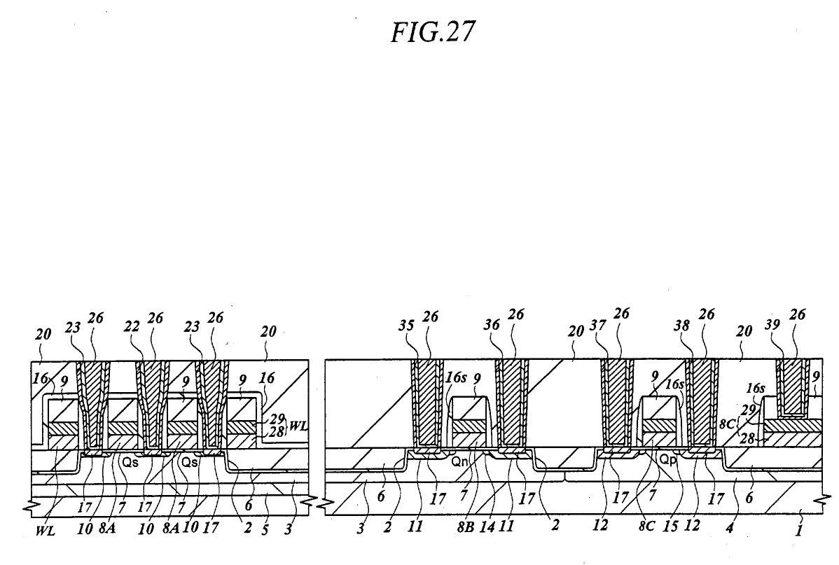

Next, as shown in FIG. 27, a silicide layer 17 is formed on the surfaces of the sources and drains of three types of MISFETs (Qs, Qn, and Qp), and, thereafter, plugs 26 are formed inside the contact holes 22, 23, and 35 to 39. The silicide layer 17 is formed by depositing a Co film (or Ti film) above the silicon oxide film 20 including the insides of the contact holes 22, 23, and 35 to 39 by a sputtering method, and by thereafter subjecting the semiconductor substrate 1 to a heat treatment. In addition, the plugs 26 are formed by depositing a TiN film and a W film by a CVD method above the Co film (or Ti film) including the insides of the contact holes 22, 23, and 35 to 39 and by thereafter polishing the W film, TiN film, and Co film (or Ti film) above the silicon oxide film 25 by a CMP method such that these films remain only inside the contact holes 22, 23, and 35 to 39. That is, according to the present embodiment, a silicide layer 17 is simultaneously formed on the surfaces of the sources and drains of the three types of MISFETs (Qs, Qn, and Qp) through same steps, and the plugs 26 inside the contact holes 22, 23, and 35 to 39 are formed simultaneously through same steps.

Although not shown in the figures, the bit lines BL of the DRAM and the first layer wires 30 to 34 of the logic LSI are thereafter formed above the silicon oxide film 20 by the same method as that of the embodiment 1 (see FIG. 15). The subsequent steps are the same as those of the embodiment 1.

According to the manufacturing method described above, the number of steps is reduced greatly after the MISFETs (Qs, Qn, and Qp) are formed until the bit lines BL and the first layer wires 30 to 34 are formed above the MISFETs (Qs, Qn, and Qp). Therefore, it is possible to simplify the process for manufacturing the DRAM-logic mixed LSI.

Also, according to the manufacturing method described above, a silicide layer 17 is also formed on the surfaces of the sources and drains (n-type semiconductor regions 10) of the memory cell selection MISFETs Qs. Therefore, the contact resistances between the sources and drains (n-type semiconductor regions 10) and the plugs 26 inside the contact holes 22 and 23 formed thereon are reduced so that high-speed operation of memory cells can be achieved. In this case, however, some consideration should be taken into increase of a leakage current where the silicide layer penetrates through the sources and drains (n-type semiconductor regions 10).

(Embodiment 3)

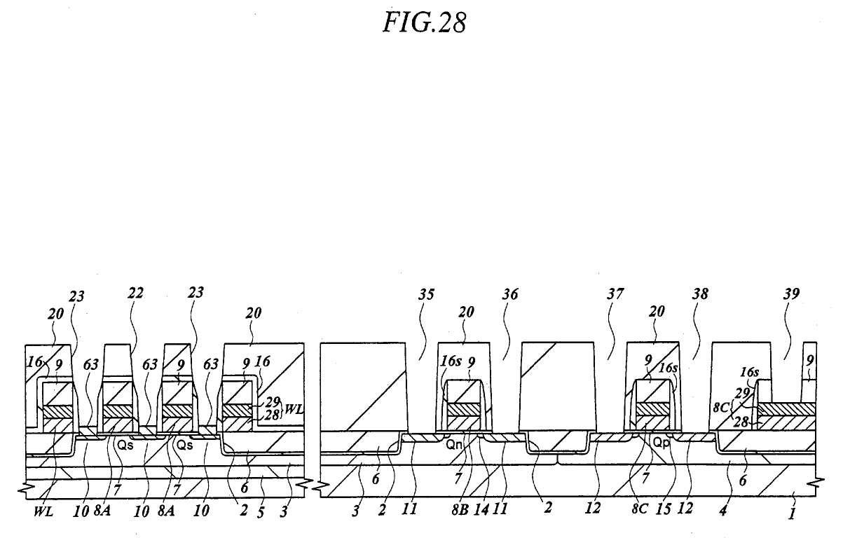

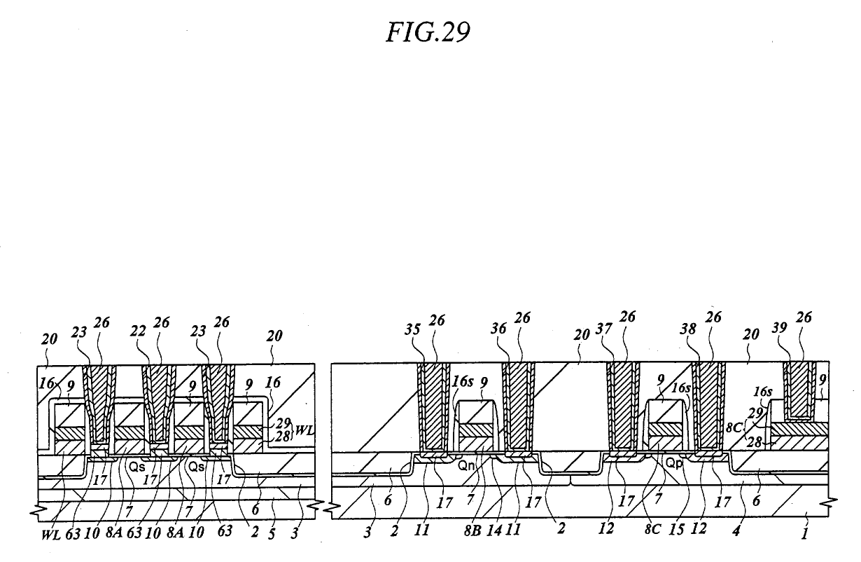

The method of manufacturing a DRAM-logic mixed LSI according to the present embodiment will be explained in the order of the manufacturing steps with reference to FIGS. 28 and 29.

At first, as shown in FIG. 26 relating to the previous embodiment 2, contact holes 22 and 23 are formed above the sources and drains (n-type semiconductor regions 10) of the memory cell selection MISFET Qs, contact holes 35 and 36 are formed above the source and drain (n⁺-type semiconductor regions 11), contact holes 37 and 38 are formed above the source and drain (p⁺-type semiconductor regions 12) of the p-channel type MISFET Qp, and a contact hole 39 is formed above the gate electrode 8C.

Next, in the present embodiment 3 as shown In FIG. 28, a silicon layer 63 doped with impurities (phosphorus or arsenic) of the same conductivity type (n-type) as that of the sources and drains (n-type semiconductor regions 10) of the memory cell selection MISFETs Qs is epitaxially grown selectively on the surfaces of these sources and drains. At this time, upper portions of the second and third regions of the semiconductor substrate 1 where the logic LSI is formed are covered with a photoresist film not shown.

Next, as shown in FIG. 29, according to the method shown in FIG. 27 relating to the previous embodiment, a silicide layer 17 is formed on the surfaces of the sources and drains of three types of MISFETs (Qs, Qn, and Qp), and thereafter, plugs 26 are formed inside the contact holes 22, 23, and 35 to 39. The subsequent steps are the same as those of the embodiment 1 or 2.

According to the manufacturing method described above, a silicon layer 63 is formed on the surfaces of the sources and drains (n-type semiconductor regions 10) of the memory cell selection MISFETs Qs, and a silicide layer 17 is formed on the surface of the silicon layer 63. Therefore, in case where the sources and drains (n-type semiconductor regions 10) are formed to be shallow, there is no risk that the silicide layer 17 penetrates through the n-type semiconductor regions 10. Therefore, according to the present embodiment, the process of manufacturing the DRAM logic mixed LSI can be simplified without deteriorating the refresh characteristics of the DRAM.

In the above description, the invention made by the present inventor has been specifically explained on the basis of embodiments thereof. However, the present invention is not limited to the embodiments described above but can be variously modified without deviating from the subject matter of the invention.

Although the above embodiments have been explained in the case where the present invention is applied to a DRAM-logic mixed LSI, the present invention is applicable, to a memory-logic mixed LSI in which the memory section is constructed as a SRAM (Static Random Access Memory) or a flash memory. Also, the present invention applicable to a memory LSI such as a DRAM, a SRAM, or a flash memory that has peripheral circuits constructed in a CMOS structure, and to a CMOS-logic LSI that does not have a memory section.

Representative aspects of the invention disclosed in the present application provide advantages as summarized in brief below.

According to the present invention, improvement of high performance of a memory-logic mixed LSI can be promoted.

Also, according to the present invention, downsizing and high integration of a memory-logic mixed LSI can be promoted.

Also, according to the present invention, process of manufacturing a memory-logic mixed LSI can be simplified.

What is claimed is:

1. A semiconductor integrated circuit device comprising an n-channel type MISFET formed in a first region of a semiconductor substrate and a p-channel type MISFET formed in a second region of the semiconductor substrate, wherein:
each of the n-channel type MISFET and the p-channel type MISFET has a gate electrode which is formed so as to include an SiGe layer and a metal layer or metal silicide layer formed above the SiGe layer, and a first insulating layer is formed above each of the gate electrodes.

2. A semiconductor integrated circuit device according to claim 1, wherein a second insulating film is formed on side walls of each of the gate electrodes of the n-channel type MISFET and the p-channel type MISFET.

3. A semiconductor integrated circuit device according to claim 2, wherein each of the n-channel type MISFET and the p-channel type MISFET has a source and a drain having surfaces on which a silicide layer is formed.

4. A semiconductor integrated circuit device according to claim 1, wherein the SiGe layer is doped with p-type impurities.

5. A semiconductor integrated circuit device according to claim 4, wherein each of the n-channel type MISFET and the p-channel type MISFET has a gate insulating film which made of silicon oxynitride.

6. A semiconductor integrated circuit device comprising a first MISFET constructing a memory element and formed in a first region of a semiconductor substrate, a second MISFET of an n-channel type formed in a second region of the semiconductor substrate, a third MISFET of a p-channel type formed in a third region of the semiconductor substrate, wherein:
each of the first to third MISFETs has a gate electrode formed so as to include an SiGe layer and a metal layer or metal silicide layer formed above the SiGe layer, and a first insulating layer is formed on each of the gate electrodes.

7. A semiconductor integrated circuit device according to claim 6, wherein the second MISFET and the third MISFET are elements constructing a logic circuit.

8. A semiconductor integrated circuit device according to claim 6, wherein a second insulating layer is formed on side walls of each of the gate electrodes of the first to third MISFETs.

9. A semiconductor integrated circuit device according to claim 8, wherein each of the first to third MISFETs has a source and a drain having surfaces on which a silicide layer is formed.

10. A semiconductor integrated circuit device according to claim 8, wherein a first layer wire is formed as an upper layer of the first to third MISFETs with an interlayer insulating film having an etching speed different from that of the first insulating layer, and the first layer wire is electrically connected to the source and drain of each of the first to third MISFETs through contact holes formed in the interlayer insulating film.

11. A semiconductor integrated circuit device according to claim 10, wherein the first insulating layer and the second insulating layer are made of a silicon-nitride-based insulating material, and the interlayer insulating film is made of a silicon-oxide-based insulating material.

12. A semiconductor integrated circuit device according to claim 8, wherein the first MISFET is an element forming a part of a memory cell of a DRAM.

13. A semiconductor integrated circuit device according to claim 12, wherein a capacity element forming another part of the memory cell of the DRAM is formed above the first MISFET, and the capacity element is electrically connected to one of the source and drain of the first MISFET through a first contact hole formed in an interlayer insulating film which covers an upper part of the first MISFET and which has an etching speed different from etching speeds of the first insulating layer and the second insulating layer.

14. A semiconductor integrated circuit device according to claim 12, wherein a bit line is formed above the first MISFET, and the bit line is electrically connected to another one of the source and drain of the first MISFET through a second contact hole formed in an interlayer insulating film which covers an upper part of the first MISFET and which has an etching speed different from etching speeds of the first insulating layer and the second insulating layer.

15. A semiconductor integrated circuit device according to claim 12, wherein the second and third MISFETs are elements forming part of a peripheral circuit of the DRAM.

16. A semiconductor integrated circuit device according to claim 12, wherein a silicon epitaxial layer is formed on surfaces of a source and a drain of the first MISFET, and a silicide layer is formed on a surface of the silicon epitaxial layer.

17. A semiconductor integrated circuit device according to claim 12, wherein a silicide layer is formed on surfaces of a source and a drain of each of the second and third MISFETs, and a silicide layer is not formed on surfaces of a source and a drain of the first MISFET.

18. A semiconductor integrated circuit device comprising an n-channel type MISFET formed in a first region of a semiconductor substrate and a p-channel type MISFET formed in a second region of the semiconductor substrate, wherein:
each of the n-channel type MISFET and the p-channel type MISFET has a gate electrode which is formed so as to include an SiGe layer and a metal layer or metal silicide layer layered above the SiGe layer, and each of the n-channel type MISFET and the p-channel type MISFET has a source and a drain having surfaces on which a silicide layer is formed.

19. A method of manufacturing a semiconductor integrated circuit device, comprising the steps of forming a first conductive film on a main surface of a semiconductor substrate, forming a first insulating film above the first conductive film, patterning thereafter the first insulating film and the first conductive film, thereby to form a gate electrode of an n-channel type MISFET and a first insulating layer covering an upper portion of the gate electrode in a first region of the semiconductor substrate and to form a gate electrode of a p-channel type MISFET and a first insulating layer covering an upper portion of the gate electrode in a second region of the semiconductor substrate, wherein:
the first conductive film forming part of the gate electrode of each of the n-channel type MISFET and the p-channel type MISFET is formed so as to include an SiGe layer and a metal layer or metal silicide layer formed above the SiGe layer.

20. A method of manufacturing a semiconductor integrated circuit device according to claim 19, further comprising steps after the gate electrode of each of the n-channel type MISFET and the p-channel type MISFET is formed, the steps being:
a step (a) of forming a second insulating layer on side walls of each of the gate electrodes, the second insulating layer being made of a material which is substantially equal to a material of the first insulating layer;
a step (b) of forming an interlayer insulating film as an upper layer of the n-channel type MISFET and the p-channel type MISFET, the interlayer insulating film having an etching speed different from etching speeds of the first and second insulating layers; and
a step (c) of etching the interlayer insulating film thereby to form a first contact hole above a source and a drain of the n-channel type MISFET by a self-alignment manner with respect to the gate electrode of the n-channel type MISFET as well as a second contact hole above a source and a drain of the p-channel type MISFET by a self-alignment manner with respect to the gate electrode of the p-channel type MISFET.

21. A method of manufacturing a semiconductor integrated circuit device according to claim 20, further comprising steps after the gate electrode of each of the n-channel type MISFET and the p-channel type MISFET is formed, the steps being:
a step (d) of forming a second conductive film above the interlayer insulating film, including insides of the first and second contact holes; and
a step (e) of subjecting the semiconductor substrate to a heat treatment thereby to form a silicide layer on surfaces of the source and drain of each of the n-channel type MISFET and the p-channel type MISFET, through reaction between the semiconductor substrate and the second conductive film.

22. A method of manufacturing a semiconductor integrated circuit device, comprising the steps of forming a first conductive film on a main surface of a semiconductor substrate, forming a first insulating film above the first conductive film, patterning thereafter the first insulating film and the first conductive film, thereby to form a first MISFET forming part of a memory element and a first insulating layer covering an upper portion of the first MISFET in a first region of the semiconductor substrate, to form a gate electrode of a second MISFET of an n-channel type and a first insulating layer covering an upper portion of the gate electrode in a second region, and to form a gate electrode of a third MISFET of a p-channel type and a first insulating layer covering an upper portion of the gate electrode in a third region, wherein:
the first conductive film forming part of the gate electrode of each of the gate electrodes of the first to third MISFETs is formed so as to include an SiGe layer and a metal layer or metal silicide layer formed above the SiGe layer.

23. A method of manufacturing a semiconductor integrated circuit device according to claim 22, further comprising steps after the gate electrode of each of the first to third MISFETs are formed, the steps being:
a step (a) of forming a second insulating layer made of a material which is substantially equal to a material of the first insulating layer, on side walls of each of the gate electrodes;
a step (b) of forming an interlayer insulating film as an upper layer of the first to third MISFETs, the interlayer insulating film having an etching speed different from etching speeds of the first and second insulating layers; and
a step (c) of etching the interlayer insulating film thereby to form a first contact hole above a source and a drain of the first MISFET by a self-alignment manner with respect to the gate electrode of the first MISFET.

24. A method of manufacturing a semiconductor integrated circuit device according to claim 23, further comprising, after the step (c):
a step (d) of forming a plug which is made of polycrystal silicon and doped with impurities of a conductivity type equal to a conductivity type of the source and drain of the first MISFET.

25. A method of manufacturing a semiconductor integrated circuit device according to claim 24, further comprising steps after the step (d), the steps being:
a step (e) of etching the interlayer insulating film thereby to form a second contact hole above a source and a drain of the second MISFET and a third contact hole above a source and a drain of the third MISFET;
a step (f) of forming a second conductive film above the interlayer insulating film, including insides of the second and third contact holes; and
a step (g) of subjecting the semiconductor substrate to a heat treatment thereby to form a silicide layer on surfaces of the source and drain of each of the second and third MISFETs, through reaction caused between the semiconductor substrate and the second conductive film.

26. A method of manufacturing a semiconductor integrated circuit device according to claim 22, further comprising steps after the gate electrode of each of the first to third MISFETs are formed, the steps being:
a step (a) of forming a second insulating layer made of a material which is substantially equal to a material of the first insulating layer, on side walls of each of the gate electrodes;
a step (b) of forming an interlayer insulating film as an upper layer of the first to third MISFETs, the interlayer insulating film having an etching speed different from etching speeds of the first and second insulating layers,;
a step (c) of etching the interlayer insulating film thereby to form a first contact hole above a source and a drain of the first MISFET by a self-alignment manner with respect to the gate electrode of the first MISFET, a second contact hole above a source and a drain of the second MISFET, and a third contact hole above a source and a drain of the third MISFET;
a step (d) of forming a second conductive film above the interlayer insulating film, including insides of the first to third contact holes; and
a step (g) of subjecting the semiconductor substrate to a heat treatment thereby to form a silicide layer on surfaces of the source and drain of each of the first to third MISFETs, through reaction caused between the semiconductor substrate and the second conductive film.

27. A method of manufacturing a semiconductor integrated circuit device according to claim 22, further comprising a step of selectively growing a silicon epitaxial layer on the surfaces of the source and drain of the first MISFET, after the step (c) and before the step (d).

28. A method of manufacturing a semiconductor integrated circuit device according to claim 22, wherein the first MISFET is an element forming part of a memory cell of a DRAM.
